(19) United States
(12) Patent Application Publication
(10) Pub. No.: US 2026/0206205 A1
(43) Pub. Date: Jul. 16, 2026

(54) SEMICONDUCTOR DEVICE INCLUDING MEMORY CELLS AND BIT LINES

(71) Applicant: Samsung Electronics Co., Ltd., Suwon-si (KR)

(72) Inventor: Jeonil Lee, Suwon-si (KR)

(21) Appl. No.: 19/449,536

(22) Filed: Jan. 15, 2026

(30) Foreign Application Priority Data
Jan. 15, 2025 (KR) 10-2025-0006350

(51) Int. Cl. H10B 12/00; G11C 11/4091

(52) U.S. Cl. CPC H10B 12/30; G11C 11/4091; H10B 12/50

(57) ABSTRACT

A semiconductor device includes a lower structure including a first structure and a second structure bonded to the first structure; and an upper structure disposed on the lower structure and including a peripheral circuit. The first structure includes lower memory cells, the second structure includes upper memory cells vertically overlapping the lower memory cells, the lower structure further includes local bit lines respectively connected to memory cell groups of the lower and upper memory cells, the second structure further includes first and second global bit lines, each of the first and second global bit lines is respectively connected to N local bit lines of the local bit lines, “N” is a natural number greater than or equal to 2, and each of the local bit lines extends through a bonded region between the first structure and the second structure.

### CROSS-REFERENCE TO RELATED APPLICATION(S

This application claims benefit of priority to Korean Patent Application No. 10-2025-0006350 filed on January 15, 2025, in the Korean Intellectual Property Office, the disclosure of which is incorporated herein by reference in its entirety.

### BACKGROUND

The present inventive concept relates to a semiconductor device including memory cells and bit lines, a method of operating the semiconductor device, and a method of manufacturing the semiconductor device.

Research is being conducted to reduce the size of elements constituting a semiconductor device and improve performance thereof. For example, in a DRAM, research is being conducted to reliably and stably form elements with reduced sizes, but as sizes of the elements are reduced, dispersion characteristics of the semiconductor device are deteriorating.

### SUMMARY

An aspect of the present inventive concept is to provide a semiconductor device capable of increasing a degree of integration.

An aspect of the present inventive concept is to provide a method of manufacturing the semiconductor device.

A semiconductor device according to an embodiment is provided. The semiconductor device includes a lower structure including a first structure and a second structure on the first structure; and an upper structure disposed on the lower structure and including a peripheral circuit. The first structure includes lower memory cells arranged three-dimensionally along a vertical direction, a first horizontal direction, and a second horizontal direction, which are perpendicular to each other, the second structure includes upper memory cells vertically overlapping the lower memory cells and arranged three-dimensionally along the vertical direction, the first horizontal direction, and the second horizontal direction, the lower structure further includes a first local bit line, a second local bit line, a third local bit line, and a fourth local bit line, with a first side surface of the first local bit line connected to a first memory cell group of the lower and upper memory cells, a second side surface of the second local bit line connected to a second memory cell group of the lower and upper memory cells, a third side surface of the third local bit line connected to a third memory cell group of the lower and upper memory cells, and a fourth side surface of the fourth local bit line connected to a fourth memory cell group of the lower and upper memory cells, the second structure further includes a first global bit line and a second global bit line, the first global bit line is connected to the first local bit line and the second local bit line and the second global bit line is connected to the third local bit line and the fourth local bit line.

A semiconductor device according to an embodiment is provided. The semiconductor device includes a lower structure including a first structure and a second structure bonded to the first structure on the first structure; and an upper structure disposed on the lower structure and including a peripheral circuit. The first structure includes lower memory cells arranged three-dimensionally along a vertical direction, a first horizontal direction, and a second horizontal direction, perpendicular to each other, the second structure includes upper memory cells vertically overlapping the lower memory cells and arranged three-dimensionally along the vertical direction, the first horizontal direction, and the second horizontal direction, the lower structure further includes local bit lines respectively connected to the memory cell groups of the lower and upper memory cells, the second structure further includes first global bit lines and second global bit lines, the peripheral circuit includes bit line sense amplifiers connected to a corresponding global bit line of the first and second global bit lines by a routing connection interconnection structure, each of the first global bit lines is respectively connected to N corresponding first local bit lines among the local bit lines, each of the second global bit lines is respectively connected to N corresponding second local bit lines among the local bit lines, “N” is a natural number greater than or equal to 2, and each of the local bit lines extends through a bonded region between the first structure and the second structure.

A semiconductor device according to an embodiment is provided. The semiconductor device includes a bit line sense amplifier; a global bit line disposed at a level lower than the bit line sense amplifier and connected to the bit line sense amplifier by a routing interconnection structure; N local bit lines disposed at a level lower than the global bit line, connected to the global bit line, and spaced apart from each other; and memory cell groups respectively connected to the local bit lines. N is a natural number greater than or equal to 2, wherein each of the memory cell groups includes a lower cell group including lower memory cells arranged in a vertical direction and an upper cell group including upper memory cells disposed on the lower cell group and arranged in the vertical direction, each of the lower memory cells and the upper memory cells includes a cell transistor and a data storage structure connected to the cell transistor, and in each of the memory cell groups, a distance between a pair of cell transistors adjacent to each other in the vertical direction among the cell transistors of the lower memory cells is smaller than a distance between an uppermost cell transistor among the cell transistors of the lower memory cells and a lowermost cell transistor among the cell transistors of the upper memory cells.

### BRIEF DESCRIPTION OF DRAWINGS

These and other aspects, features, and advantages of the present inventive concept will be more clearly understood from the following detailed description, taken in conjunction with the accompanying drawings, in which:

FIGS. 1, 2, 3, and 4 are views illustrating semiconductor devices according to embodiments.

FIGS. 5, 6, 7A, 7B, and 8 are views illustrating a semiconductor device according to an embodiment.

FIG. 9 is a partially enlarged cross-sectional view illustrating a semiconductor device according to an embodiment.

FIGS. 10A, 10B, and 11 are views illustrating a semiconductor device according to an embodiment.

FIG. 12 is a partially enlarged cross-sectional view illustrating a semiconductor device according to an embodiment.

FIGS. 13, 14, 15, 16, and 17 are views illustrating a semiconductor device according to an embodiment.

FIGS. 18, 19, and 20 are views illustrating a semiconductor device according to an embodiment.

FIGS. 21 and 22 are views illustrating a semiconductor device according to an embodiment.

FIGS. 23 to 30, and 31A, 31B, 31C, and 31D are views illustrating an example of a method for manufacturing a semiconductor device according to an embodiment.

FIGS. 32A, 32B, 32C, and 32D are views illustrating an example of a method for manufacturing a semiconductor device according to an embodiment.

FIGS. 33, 34A, 34B, and 34C are views illustrating an example of a method for manufacturing a semiconductor device according to an embodiment.

FIGS. 35, 36A, 36B, and 36C are views illustrating an example of a method for manufacturing a semiconductor device according to an embodiment.

FIG. 37 is a process flow diagram illustrating an example of a method for manufacturing a semiconductor device according to an embodiment.

FIG. 38 is a process flow diagram illustrating an example of a method for manufacturing a semiconductor device according to an embodiment.

### DETAILED DESCRIPTION

The present disclosure will now be described more fully hereinafter with reference to the accompanying drawings, in which various embodiments are shown. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. Items described in the singular herein may be provided in plural, as can be seen, for example, in the drawings. Thus, the description of a single item that is provided in plural should be understood to be applicable to the remaining plurality of items unless context indicates otherwise. The language of the claims should be referenced in determining the requirements of the invention.

Throughout the specification, when a component is described as "including" a particular element or group of elements, it is to be understood that the component may be formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being "connected" or "coupled" to or “on” another element, it can be directly connected or coupled to or on the other element or intervening elements may be present. In contrast, when an element is referred to as being "directly connected" or "directly coupled" to another element, or as “contacting” or “in contact with” another element (or using any form of the word “contact”), there are no intervening elements present at the point of contact.

As used herein, components described as being “electrically connected” are configured such that an electrical signal can be conducted from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes. Directly electrically connected elements may be directly physically connected and directly electrically connected.

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

Hereinafter, spatially relative terms such as “upper,” “lower,” “lower portion,” “upper portion,” “upper end,” “lower end,” and the like may be used herein for ease of description to describe positional relationships, such as illustrated in the figures, for example. It will be understood that the spatially relative terms encompass different orientations of the device in addition to the orientation depicted in the drawings.

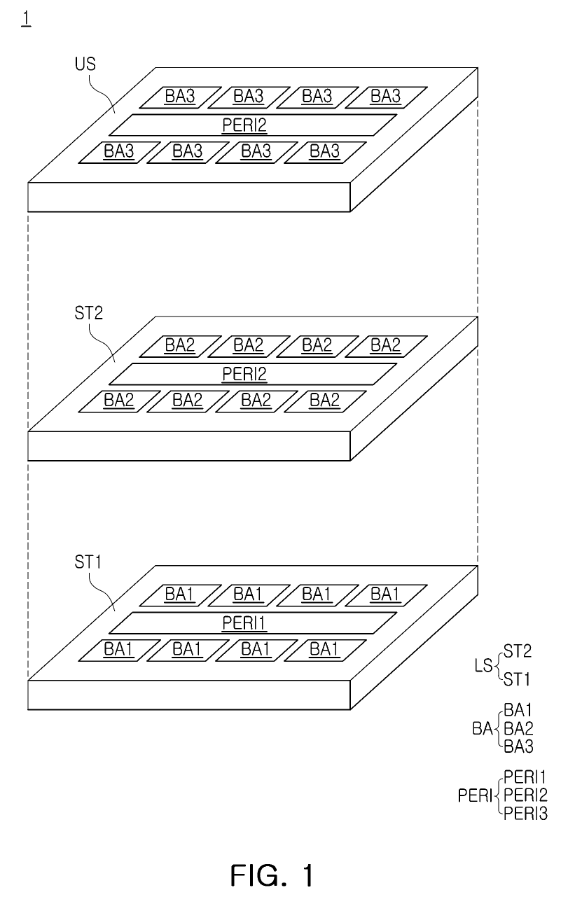

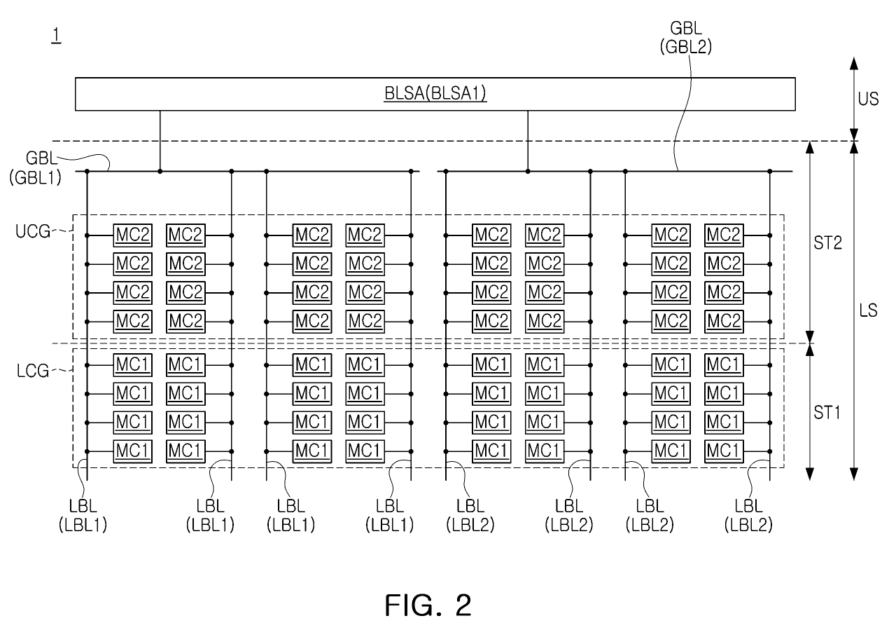

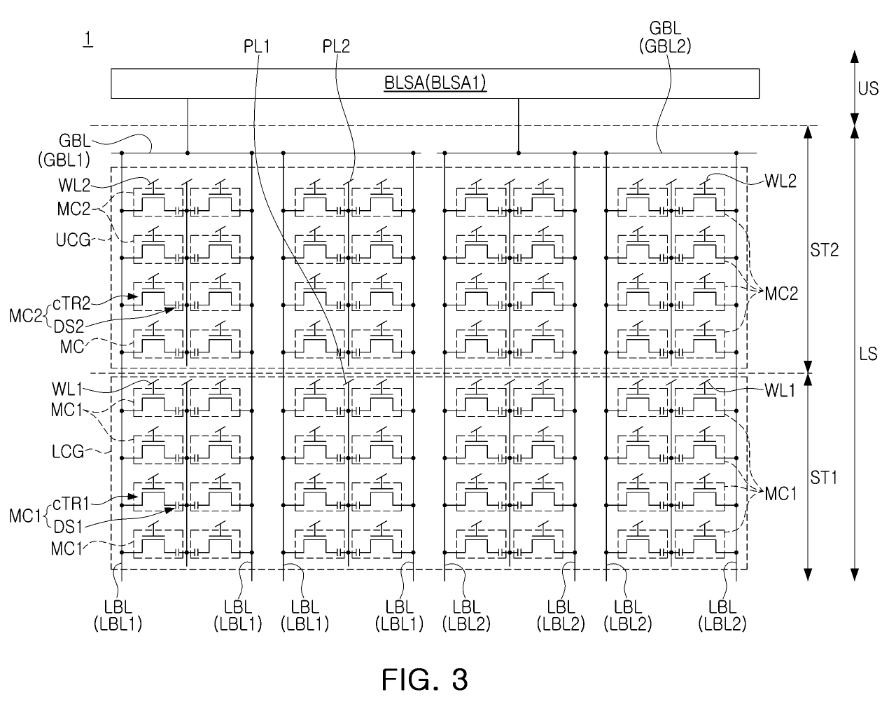

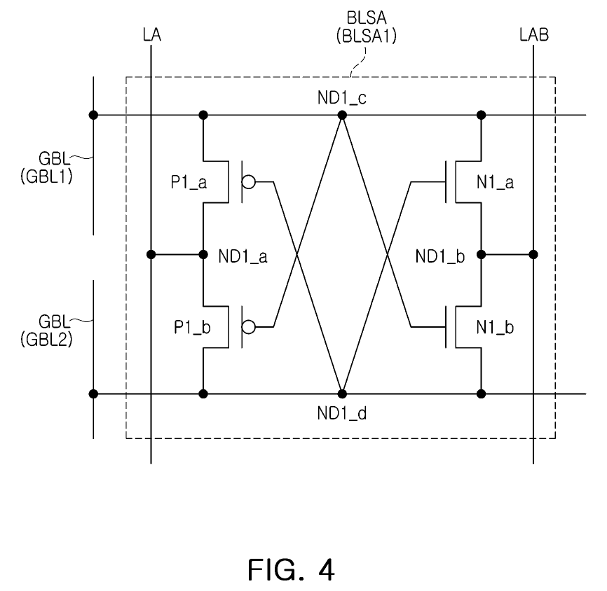

FIGS. 1, 2, 3, and 4 illustrate a semiconductor device according to an embodiment. FIG. 1 is a conceptual perspective view illustrating a semiconductor device according to an embodiment, FIG. 2 is a conceptual diagram illustrating a semiconductor device according to an embodiment, FIG. 3 is a view including circuits of memory cells of a memory cell group in a semiconductor device according to an embodiment, and FIG. 4 is a circuit diagram illustrating an example of a bit line sense amplifier in a semiconductor device according to an embodiment.

Referring to FIGS. 1, 2, 3, and 4, a semiconductor device 1 according to an embodiment may include a lower structure LS and an upper structure US on the lower structure LS. The lower structure LS may include a first structure ST1 and a second structure ST2 on the first structure ST1.

The semiconductor device 1 may include a plurality of banks BA and an outer peripheral region PERI. The outer peripheral region PERI may include a first peripheral region PERI1 in the first structure ST1, a second peripheral region PERI2 in the second structure ST2, and a third peripheral circuit PERI3 in the upper structure US. The outer peripheral region PERI may be a peripheral circuit region in which peripheral circuits for input/output of data or commands, or input of power/ground are disposed.

Each of the plurality of banks BA may include a first bank area BA1 in the first structure ST1, a second bank area BA2 in the second structure ST2, and a third bank area BA3 in the upper structure US.

The first bank area BA1 of the first structure ST1 may include lower memory cells MC1 arranged three-dimensionally, and the second bank area BA2 of the second structure ST2 may include upper memory cells MC2 arranged three-dimensionally. The upper memory cells MC2 may be disposed on the lower memory cells MC1.

The lower structure LS may further include local bit lines LBL connected to the lower memory cells MC1 and the upper memory cells MC2. Each of the local bit lines LBL may be formed of, but is not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, or a combination thereof.

The second structure ST2 may further include global bit lines GBL connected to the local bit lines LBL.

The global bit lines GBL may further include first global bit lines GBL1 and second global bit lines GBL2. Each of the first global bit lines GBL1 may be connected to N first local bit lines LBL1 among the local bit lines LBL, and each of the second global bit lines GBL2 may be connected to N second local bit lines LBL2 among the local bit lines LBL. “N” may be a natural number greater than or equal to 2. For example, the N first local bit lines LBL1 may include a first local bit line and a second local bit line, and the N second local bit lines LBL2 may include a third local bit line and a fourth local bit line.

Side surfaces of the first local bit lines LBL1 may be connected to first lower memory cells among the lower memory cells MC1 and first upper memory cells among the upper memory cells MC2, and side surfaces of the second local bit lines LBL2 may be connected to second lower memory cells among the lower memory cells MC1 and second upper memory cells among the upper memory cells MC2. For example, a first side surface of the first local bit line may be connected to a first memory cell group of the lower and upper memory cells, a second side surface of the second local bit line may be connected to a second memory cell group of the lower and upper memory cells, a third side surface of the third local bit line may be connected to a third memory cell group of the lower and upper memory cells, and a fourth side surface of the fourth local bit line may be connected to a fourth memory cell group of the lower and upper memory cells.

The lower and upper memory cells MC1 and MC2 may be defined as a memory cell group (LCG and UCG). For example, the memory cell group (LCG and UCG) may include the lower and upper memory cells MC1 and MC2 connected to each of the local bit lines LBL and arranged in a vertical direction in sequence. The memory cell group (LCG and UCG) may include a lower cell group LCG including the lower memory cells MC1 disposed in the first structure ST1, and an upper cell group UCG including the upper memory cells MC2 disposed in the second structure ST2.

Each of the lower memory cells MC1 may include a first cell transistor cTR1 and a first data storage structure DS1 connected to the first cell transistor cTR1. Each of the upper memory cells MC2 may include a second cell transistor cTR2 and a second data storage structure DS2 connected to the second cell transistor cTR2. The first and second data storage structures DS1 and DS2 may be cell capacitors capable of storing data in a memory such as a DRAM or the like. In each of the memory cell groups, a distance between a pair of cell transistors (e.g., cTR1 and cTR2) adjacent to each other in the vertical direction is less than a distance between an uppermost cell transistor among the cell transistors of the lower memory cells and a lowermost cell transistor among the cell transistors of the upper memory cells. For example, insulating layers between the first structure and the second structure may result in the increased distance between an uppermost cell transistor among the cell transistors of the lower memory cells and a lowermost cell transistor among the cell transistors of the upper memory cells in a memory cell group.

The third bank area BA3 of the upper structure US may include a peripheral circuit such as a sense amplifier area, a sub word line driver area, or the like. For example, the third bank area BA3 of the upper structure US may include bit line sense amplifiers BLSA.

Each of the bit line sense amplifiers BLSA may be connected to a first global bit line GBL1 and a second global bit line GBL2, adjacent to each other, among the first and second global bit lines GBL1 and GBL2. For example, a first bit line sense amplifier BLSA1 of the bit line sense amplifiers BLSA may be connected to the first global bit line GBL1 and the second global bit line GBL2.

Each of the bit line sense amplifiers BLSA may include a plurality of transistors P1_a, P1_b, N1_a, and N1_b. The transistors P1_a, P1_b, N1_a, and N1_b may include a P1_a transistor and a P1_b transistor, which are PMOS transistors, and an N1_a transistor and an N1_b transistor, which are NMOS transistors. The P1_a transistor and the P1_b transistor may be referred to as a PMOS transistor pair, and the N1_a transistor and the N1_b transistor may be referred to as an NMOS transistor pair. A source of the P1_a transistor and a source of the P1_b transistor may be connected to a first control line LA through a first node ND1_a. A source of the N1_a transistor and a source of the N1_b transistor may be connected to a second control line LAB through a second node ND1_b. The first node ND1_a and the second node ND1_b may be referred to as a first source node and a second source node, respectively. A drain of the P1_a transistor and a drain of the N1_a transistor may be connected to a first global bit line GBL1 among the global bit lines GBL through a first drain node ND1_c. A drain of the P1_b transistor and a drain of the N1_b transistor may be connected to a complementary bit line, e.g., a second global bit line GBL2, among the global bit lines GBL through a second drain node ND1_d. The bit line sense amplifier BLSA may sense a voltage change amount of the first global bit line GBL1, and may amplify the same. In the bit line sense amplifier BLSA, when performing sensing and amplifying operations, an internal power voltage may be applied to the first node ND1_a through the first control line LA, and the second node ND1_b may be connected to a ground terminal through the second control line LAB. The bit line sense amplifier BLSA may include a PMOS transistor pair and an NMOS transistor pair, and may be implemented with a circuit configuration in which transistors are cross-coupled, but as an example embodiment, and the embodiments are not limited thereto. For example, the circuit of the bit line sense amplifier BLSA may be implemented with various circuit configurations.

In the embodiments, the global bit lines GBL may be disposed between the local bit lines LBL and the bit line sense amplifiers BLSA, the total number of the bit line sense amplifiers BLSA may be smaller than the total number of the first local bit lines LBL1. Therefore, since an area occupied by the bit line sense amplifiers BLSA may be reduced, a degree of integration of the semiconductor device 1 may increase.

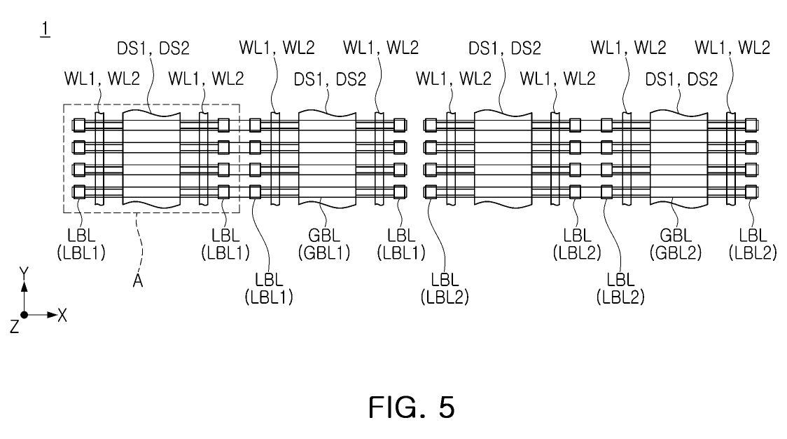

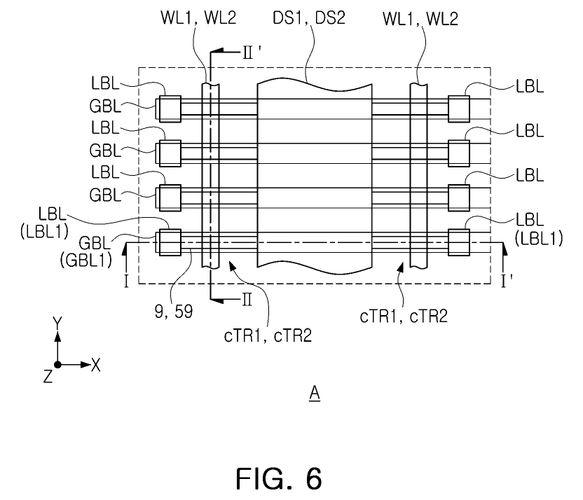

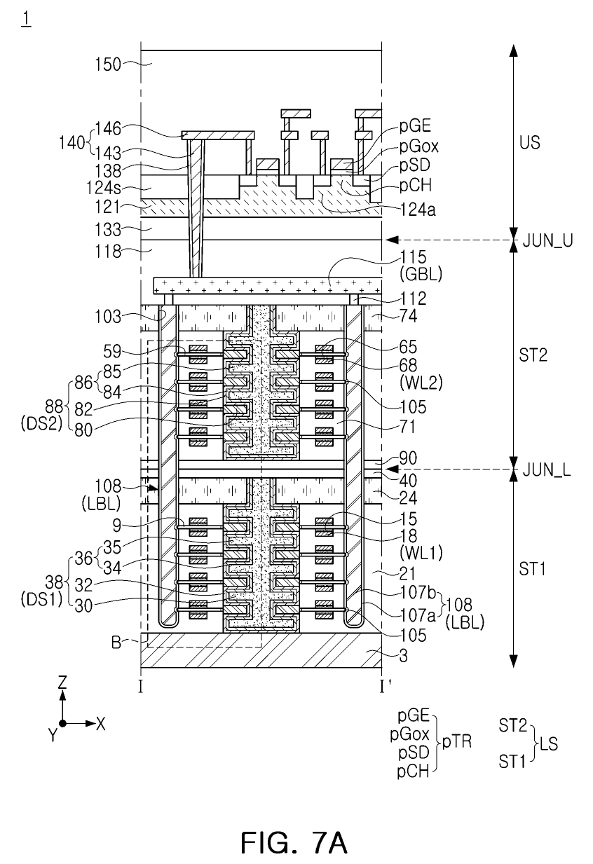

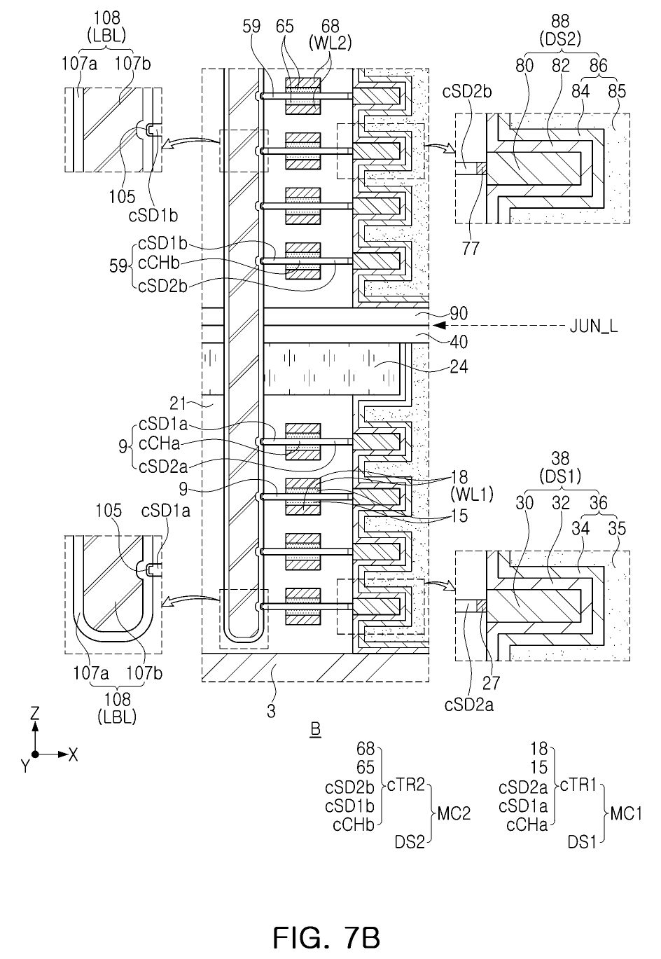

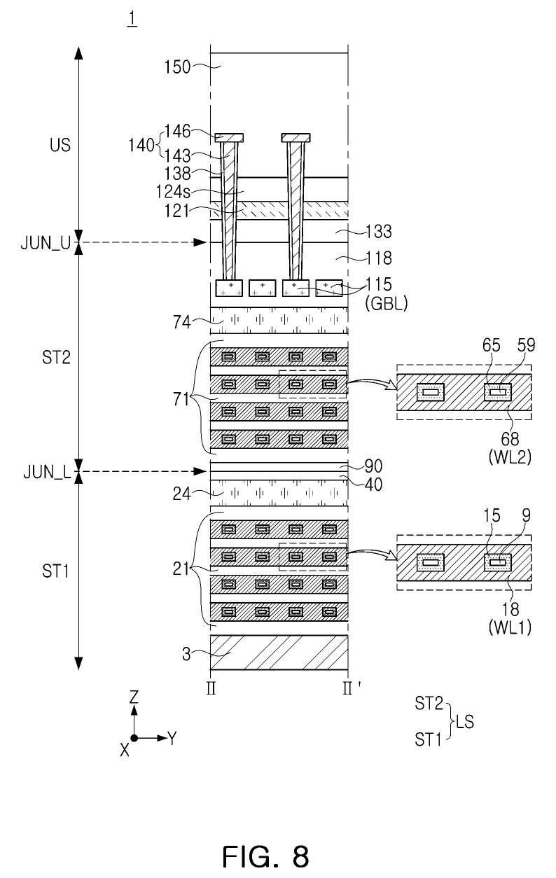

Next, with reference to FIGS. 5, 6, 7A, 7B, and 8, together with FIGS. 1 to 4, an example of a semiconductor device according to an embodiment will be described. In FIGS. 5, 6, 7A, 7B, and 8, FIG. 5 is a plan view illustrating an example of a semiconductor device according to an embodiment, FIG. 6 is an enlarged partial plan view illustrating a portion indicated by ‘A’ in FIG. 5, FIG. 7A is a cross-sectional view illustrating an area of FIG. 6, taken along line I-I’, FIG. 7B is an enlarged partial cross-sectional view illustrating an area indicated by ‘B’ of FIG. 7A, and FIG. 8 is a cross-sectional view illustrating an area of FIG. 6, taken along line II-II’.

Referring to FIGS. 5, 6, 7A, 7B, and 8, together with FIGS. 1 to 4, the first structure ST1 may further include a base 3 and lower active patterns 9 disposed on the base 3. The lower active patterns 9 may be formed of a semiconductor material that may be used as a channel region of a transistor. For example, each of the lower active patterns 9 may include a single crystal silicon semiconductor or an oxide semiconductor.

Each of the lower active patterns 9 may include a first lower source/drain region cSD1a and a second lower source/drain region cSD2a, spaced apart from each other in the first horizontal direction (X), and a lower channel region cCHa between the first and second lower source/drain regions cSD1a and cSD2a.

The first structure ST1 may include lower cell gate electrodes 18 vertically overlapping the lower channel regions cCHa, and lower cell gate dielectric layers 15 between the lower cell gate electrodes 18 and the lower channel regions cCHa. The lower cell gate electrodes 18 may be stacked while being spaced apart from each other in the vertical direction (Z). Each of the lower cell gate electrodes 18 may surround a corresponding lower channel region cCHa among the lower channel regions cCHa in the second horizontal direction (Y), perpendicular to the first horizontal direction (X), and may extend in the second horizontal direction (Y).

Each of the first cell transistors cTR1 described above may include the lower channel region cCHa, the first and second lower source/drain regions cSD1a and cSD2a, the lower cell gate dielectric layer 15, and the lower cell gate electrode 18.

Each of the first data storage structures DS1 described above may be a first data storage structure 38 including a first electrode 30 connected to a corresponding second lower source/drain region cSD2a among the second lower source/drain regions cSD2a, a second electrode 36 covering the first electrode 30, and a dielectric layer 32 between the first electrode 30 and the second electrode 36. The first electrode 30 may have a pillar shape extending in the first horizontal direction (X). The second electrode 36 may include a first electrode material layer 34 contacting the dielectric layer 32 and a second electrode material layer 35 contacting the first electrode material layer 34.

In the first data storage structures DS1, a lower surface of each of the second electrodes 36 may be disposed at a level lower than a lowermost cell transistor among the first cell transistors cTR1, and an upper surface of each of the second electrodes 36 may be disposed at a level higher than an uppermost cell transistor among the first cell transistors cTR1. Each of the second electrodes 36 may extend in the second horizontal direction (Y).

The lower memory cells MC1 including the first cell transistors cTR1 and the first data storage structures DS1 may be arranged three-dimensionally along the vertical direction (Z), the first horizontal direction (X), and the second horizontal direction (Y), perpendicular to each other.

The first structure ST1 may further include a lower insulating structure 21 disposed on the base 3 and on side surfaces of the second electrodes 36. The first cell transistors cTR1 may be embedded in the lower insulating structure 21. The first structure ST1 may further include a lower capping insulating layer 24 disposed on the insulating structure 21 and disposed between the second electrodes 36. The first structure ST1 may further include a first insulating layer 40 on the lower capping insulating layer 24 and the second electrodes 36.

The second electrodes 36 of the first data storage structures DS1 may be plate electrodes PL1 connected to each other.

The second structure ST2 may include a second insulating layer 90 bonded to the first insulating layer 40. Therefore, the second insulating layer 90 of the second structure ST2 and the first insulating layer 40 of the first structure ST1 may be bonded to form a first bonded region JUN_L.

The second structure ST2 may further include upper active patterns 59 disposed on the second insulating layer 90. The upper active patterns 59 may be formed of the same material as the lower active patterns 9.

Each of the upper active patterns 59 may include a first upper source/drain region cSD1b and a second upper source/drain region cSD2b, spaced apart from each other in the first horizontal direction (X), and an upper channel region cCHb between the first and second upper source/drain regions cSD1b and cSD2b.

The second structure ST2 may include upper cell gate electrodes 68 vertically overlapping the upper channel regions cCHb, and upper cell gate dielectric layers 65 between the upper cell gate electrodes 68 and the upper channel regions cCHb.

The upper cell gate electrodes 68 may be stacked while being spaced apart from each other in the vertical direction (Z). Each of the upper cell gate electrodes 68 may surround a corresponding upper channel region cCHb among the upper channel regions cCHb in the second horizontal direction (Y), and may extend in the second horizontal direction (Y).

Each of the second cell transistors cTR2 described above may include the upper channel region cCHb, the first and second upper source/drain regions cSD1b and cSD2b, the upper cell gate dielectric layer 65, and the upper cell gate electrode 68.

The lower cell gate electrodes 18 may be first word lines WL1, and the upper cell gate electrodes 68 may be second word lines WL2.

Each of the second data storage structures DS2 described above may be a second data storage structure 88 including a first electrode 80 connected to a corresponding second upper source/drain region cSD2b among the second upper source/drain regions cSD2b, a second electrode 86 covering the first electrode 80, and a dielectric layer 82 between the first electrode 80 and the second electrode 86. The first electrode 80 may have a pillar shape extending in the first horizontal direction (X). The second electrode 86 may include a first electrode material layer 84 contacting the dielectric layer 82 and a second electrode material layer 85 contacting the first electrode material layer 84.

In the second data storage structures DS2, a lower surface of each of the second electrodes 86 may be disposed at a level lower than a lowermost cell transistor among the second cell transistors cTR2, and an upper surface of each of the second electrodes 86 may be disposed at a level higher than an uppermost cell transistor among the second cell transistors cTR2. Each of the second electrodes 86 may extend in the second horizontal direction (Y).

The second electrodes 86 of the second data storage structures DS2 may be plate electrodes PL2 connected to each other.

The upper memory cells MC2 including the second cell transistors cTR2 and the second data storage structures DS2 may be arranged three-dimensionally along the vertical direction (Z), the first horizontal direction (X), and the second horizontal direction (Y), perpendicular to each other.

The second structure ST2 may further include an upper insulating structure 71 disposed on the second insulating layer 90 and disposed on side surfaces of the second electrodes 86. The second cell transistors cTR2 may be embedded in the upper insulating structure 71. The second structure ST2 may further include an upper capping insulating layer 74 disposed on the upper insulating structure 71 and disposed between the second electrodes 86.

Side surfaces of the first local bit lines LBL1 may be connected to first lower memory cells among the lower memory cells MC1 and first upper memory cells among the upper memory cells MC2, and side surfaces of the second local bit lines LBL2 may be connected to second lower memory cells among the lower memory cells MC1 and second upper memory cells among the upper memory cells MC2.

The side surfaces of the first local bit lines LBL1 may be connected to the first lower source/drain regions cSD1a and the first upper source/drain regions cSD1b of the cell transistors cTR1 and cTR2 of the first lower memory cells (MC1) and the first upper memory cells (MC2), and the side surfaces of the second local bit lines LBL2 may be connected to the first lower source/drain regions cSD1a and the first upper source/drain regions cSD1b of the cell transistors cTR1 and cTR2 of the second lower memory cells (MC1) and the second upper memory cells (MC2).

The local bit lines LBL may have recessed side surfaces that contact the lower memory cells MC1 and the upper memory cells MC2. Each of the local bit lines LBL may be a conductive pillar 108 extending from a level lower than a channel region cCHa of a first cell transistor cTR1 of a lowermost memory cell among the lower memory cells MC1 to a level higher than a channel region cCHb of a second cell transistor cTR2 of an uppermost memory cell among the upper memory cells MC2. The conductive pillar 108 may penetrate through the upper capping insulating layer 74, the upper insulating structure 71, the first and second insulating layers 40 and 90, and the lower capping insulating layer 24, and may extend into the lower insulating structure 21. The local bit lines LBL, e.g., the conductive pillars 108, may penetrate through the first bonded region JUN_L.

The conductive pillar 108 may include a pillar pattern 107b and a conductive liner 107a covering side and lower surfaces of the pillar pattern 107b. The conductive liner 107a may include at least one of doped polysilicon and a metal nitride. For example, the conductive liner 107a may include at least one of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, or CoSi, and the pillar pattern 107b may include a material different from a material of the conductive liner 107a, and may include at least one of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, or CoSi.

The lower structure LS may further include metal-semiconductor compound layers 105 disposed between the conductive pillar 108 and the lower active patterns 9, and between the conductive pillar 108 and the upper active patterns 59.

The second structure ST2 may further include contact plugs 112 electrically connecting the global bit lines GBL and the local bit lines LBL between the global bit lines GBL and the local bit lines LBL.

The second structure ST2 may further include a third insulating layer 118 on the global bit lines GBL.

The upper structure US may further include a fourth insulating layer 133, a substrate 121 on the fourth insulating layer 133, peripheral transistors pTR disposed on the substrate 121, a routing interconnection structure 140, and an upper insulating structure 150 covering the peripheral transistors pTR on the substrate 121.

The third insulating layer 118 of the second structure ST2 and the fourth insulating layer 133 of the upper structure US may be bonded to form a second bonded region JUN_U between the second structure ST2 and the upper structure US.

Each of the peripheral transistors pTR may include peripheral source/drain regions pSD disposed in a peripheral active region 124a, a peripheral channel region pCH between the peripheral source/drain regions pSD, a peripheral gate electrode pGE on the peripheral channel region pCH, and a peripheral gate dielectric layer pGox between the peripheral gate electrode pGE and the peripheral channel region pCH. The peripheral active region 124a may be defined by a device isolation region 124s disposed on the substrate 121.

The routing interconnection structure 140 may include a through-electrode 143 penetrating through the substrate 121, and a connecting interconnection 146 electrically connecting the through-electrode 143 and the peripheral transistor pTR on the substrate 121. The through-electrode 143 may be spaced apart from the substrate 121 by an insulating spacer 138 on a side surface of the through-electrode 143.

Hereinafter, example embodiments of the semiconductor device 1 will be described. Various example embodiments described below and the embodiments described above may be combined with each other to form an example embodiment. Hereinafter, the elements described above may be referred to without a separate detailed description, or a separate description thereof may be omitted. In addition, the elements described with reference to the drawings below, which may be modified versions of previously described elements, may replace previously described elements, or may be added to previously described elements, may be combined with each other or with the elements described above to form a semiconductor device according to an embodiment. In addition, although the described elements may be present as a plurality of like elements in a semiconductor device according to an embodiment, the following description will focus on a case in which the number of the elements described above is one with the understanding that the description may be applicable to each element of a plurality of elements.

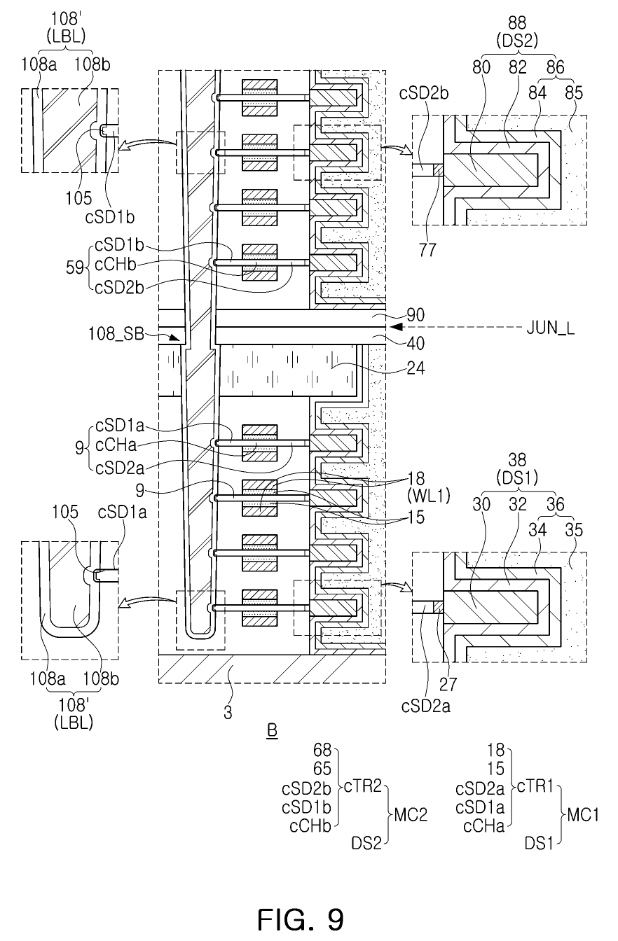

Hereinafter, an example of a semiconductor device according to an embodiment will be described with reference to FIG. 9. FIG. 9 is a partially enlarged cross-sectional view illustrating an example of a semiconductor device according to an embodiment, which may illustrate a modified example of the conductive pillar 108 of the local bit line LBL of FIG. 7B.

In an embodiment, referring to FIG. 9, the local bit line LBL, e.g., the conductive pillar (108 of FIGS. 7A and 7B) described above may be replaced with a conductive pillar 108’ as in FIG. 9. For example, a side surface of the conductive pillar 108’ of each of the local bit lines LBL may have a bend portion 108_SB at a level lower than the first bonded region JUN_L and higher than a cell transistor cTR1 of an uppermost memory cell among the lower memory cells MC1.

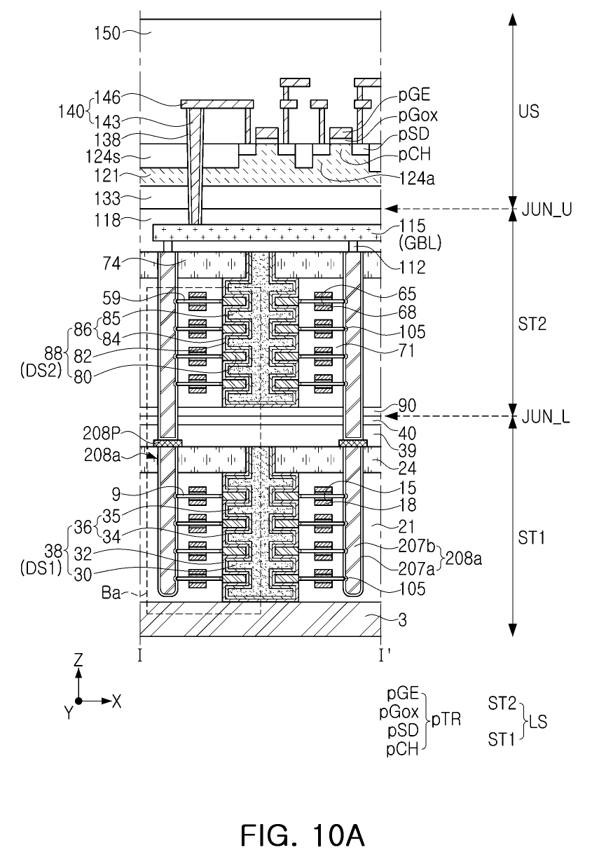

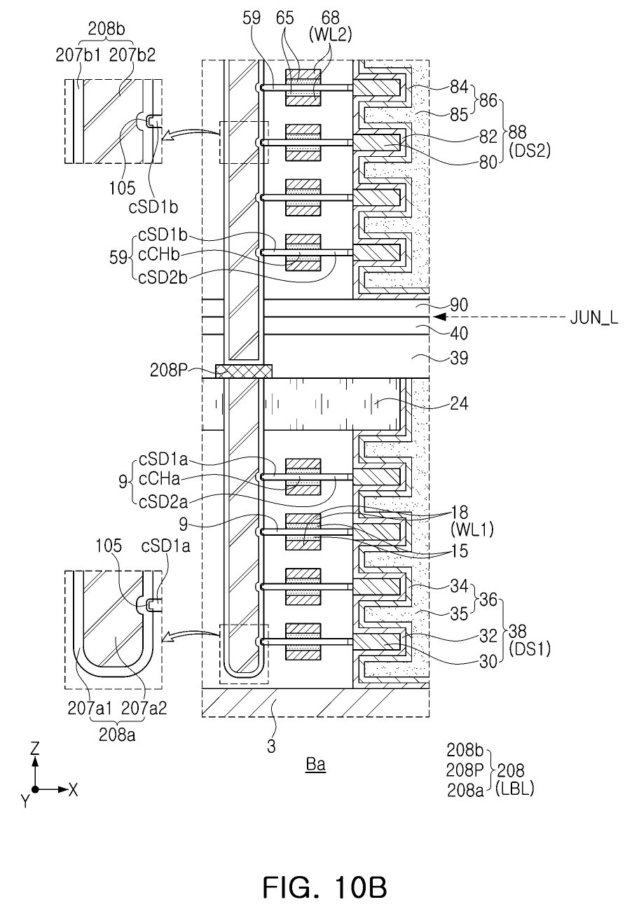

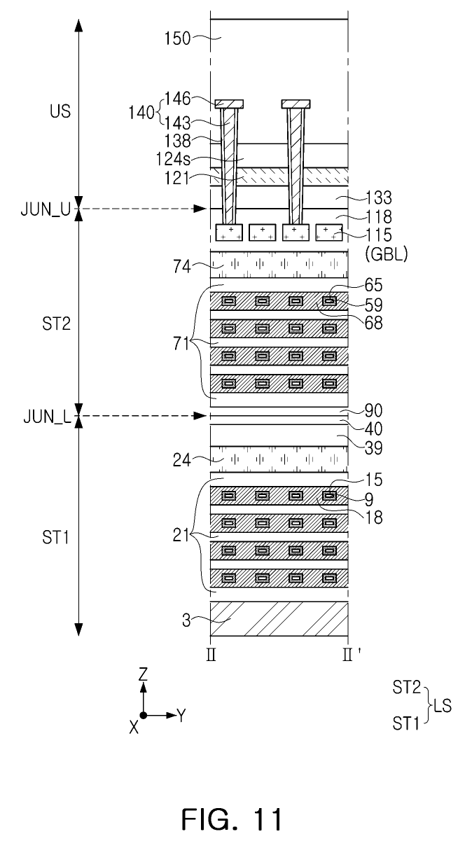

Hereinafter, examples of semiconductor devices according to an embodiment will be described with reference to FIGS. 10A, 10B, and 11. FIGS. 10A, 10B, and 11 are views illustrating examples of semiconductor devices according to an embodiment, which may illustrate modified examples of the conductive pillar 108 of the local bit line LBL of FIG. 7B. In FIGS. 10A, 10B, and 11, FIG. 10A is a cross-sectional view illustrating an area of FIG. 6, taken along line I-I’, FIG. 10B is a partially enlarged cross-sectional view illustrating an area indicated by ‘Ba’ of FIG. 10A, and FIG. 11 may be a cross-sectional view illustrating an area of FIG. 6, taken along line II-II’.

In an embodiment, referring to FIGS. 10A, 10B and 11, the local bit line LBL, e.g., the conductive pillar (108 of FIGS. 7A and 7B) described above may be replaced with a conductive pillar 208 as in FIGS. 10A and 10B. For example, the conductive pillar 208 of each of the local bit lines LBL may include a lower conductive pillar 208a connected to the first lower source/drain regions cSD1a of a corresponding lower memory cells MC1 among the lower memory cells MC1, an upper conductive pillar 208b connected to the first upper source/drain regions cSD1b of a corresponding upper memory cells MC2 among the upper memory cells MC2, and a landing pad 208P between the lower conductive pillar 208a and the upper conductive pillar 208b.

The first structure ST1 may further include an interlayer insulating layer 39 between the first insulating layer 40 and the lower capping insulating layer 24.

The landing pad 208P may be disposed on the lower capping insulating layer 24 and the lower conductive pillar 208a. The landing pad 208P may be in contact with an upper surface of the lower conductive pillar 208a. The lower conductive pillar 208a may extend downward through the lower capping insulating layer 24, and may be connected to the first lower source/drain regions cSD1a. The upper conductive pillar 208b may extend downward through the upper capping insulating layer 74, the upper insulating structure 71, the second insulating layer 90, the first bonded region JUN_L, and the first insulating layer 40, and may be connected to the landing pad 208P.

The lower conductive pillar 208a may include a pillar pattern 207a2 and a conductive liner 207a1 covering side and lower surfaces of the pillar pattern 207a2. The upper conductive pillar 208b may include a pillar pattern 207b2 and a conductive liner 207b1 covering side and lower surfaces of the pillar pattern 207b2.

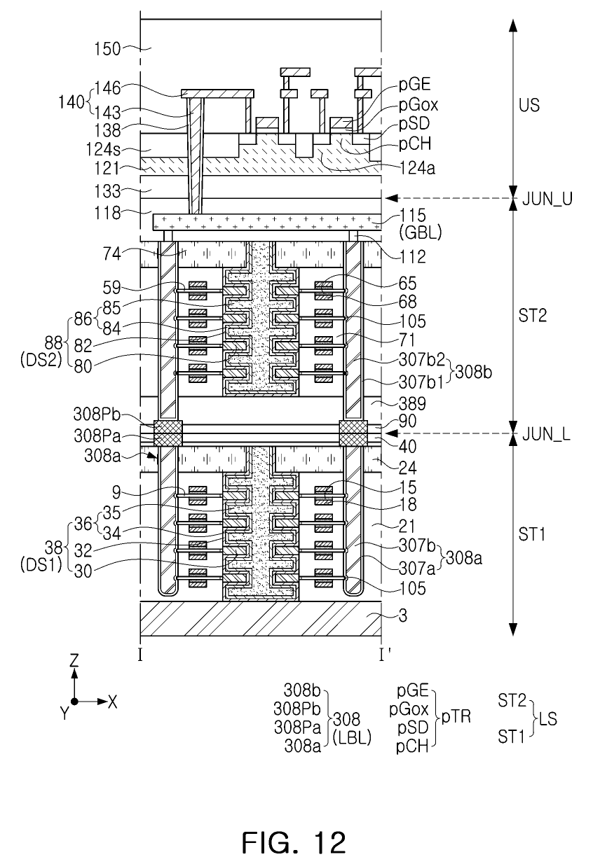

An example of a semiconductor device according to an embodiment will be described with reference to FIG. 12. FIG. 12 is a view illustrating an example of a semiconductor device according to an embodiment, and may illustrate a modified example of the conductive pillar 108 of the local bit line LBL of FIG. 7B. FIG. 12 may be a cross-sectional view illustrating an area of FIG. 6, taken along line I-I’.

In an embodiment, referring to FIG. 12, the local bit line LBL, e.g., the conductive pillar (108 of FIGS. 7A and 7B) described above may be replaced with a conductive pillar 308 as illustrated in FIG. 12. For example, each of the local bit lines LBL may include a lower conductive pillar 308a connected to the first lower source/drain regions cSD1a of corresponding lower memory cells MC1 among the lower memory cells MC1, an upper conductive pillar 308b connected to the first upper source/drain regions cSD1b of corresponding upper memory cells MC2 among the upper memory cells MC2, a lower bonding pad 308Pa connected to an upper surface of the lower conductive pillar 308a, and an upper bonding pad 308Pb contacting the lower bonding pad 308Pa and connected to the upper conductive pillar 308b.

The first structure ST1 may further include an interlayer insulating layer 304 between the first insulating layer 40 and the lower capping insulating layer 24, and the second structure ST2 may further include an interlayer insulating layer 389 disposed between the second insulating layer 90 and the upper insulating structure 71, and between the second insulating layer 90 and the data storage structure DS2.

The lower bonding pad 308Pa may penetrate through the first insulating layer 40, and the upper bonding pad 308Pb may penetrate through the second insulating layer 90, and be bonded to the lower bonding pad 308Pa. The lower conductive pillar 308a may be connected to the lower bonding pad 308Pa, and may extend downward to be connected to the first lower source/drain regions cSD1a. The upper conductive pillar 308b may penetrate through the upper capping insulating layer 74, the upper insulating structure 71, and the interlayer insulating layer 389, and may be connected to the upper bonding pad 308Pb.

The lower conductive pillar 308a may include a pillar pattern 307b and a conductive liner 307a covering side and lower surfaces of the pillar pattern 307b. The upper conductive pillar 308b may include a pillar pattern 307b2 and a conductive liner 307b1 covering side and lower surfaces of the pillar pattern 307b2.

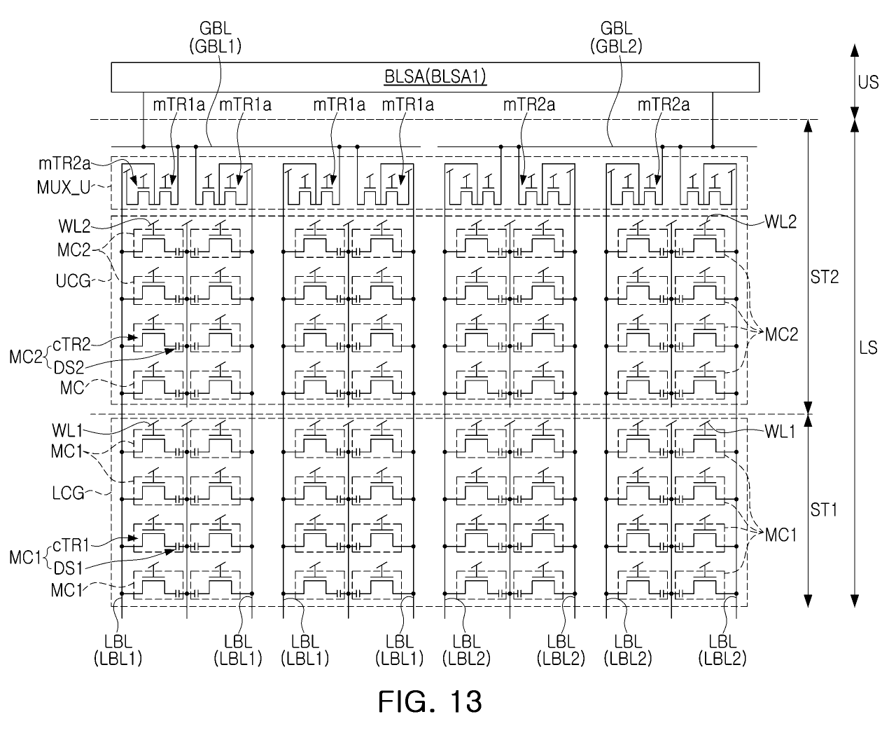

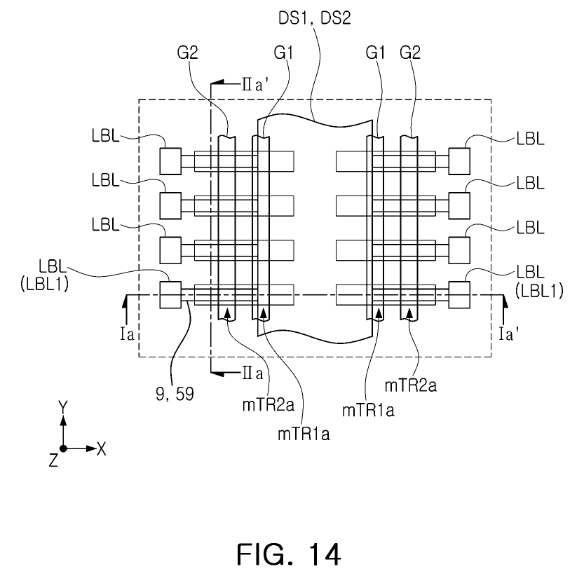

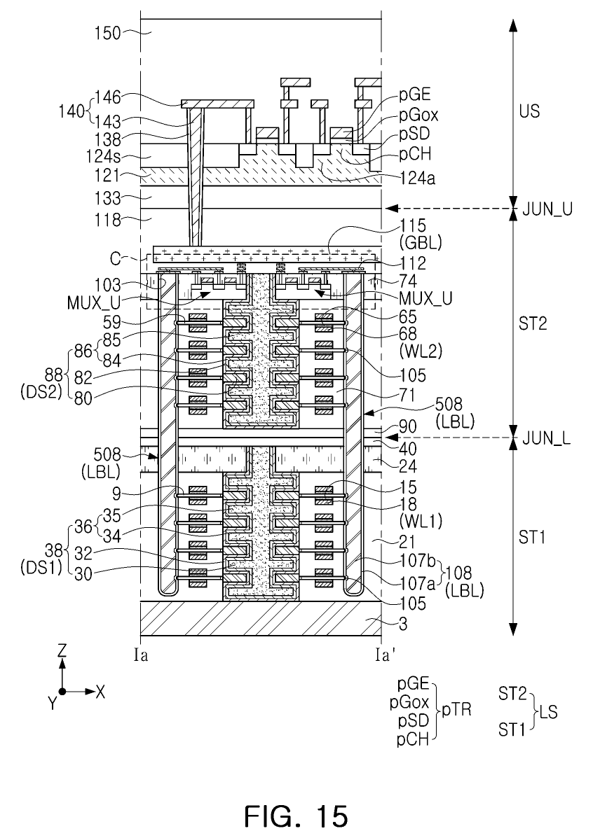

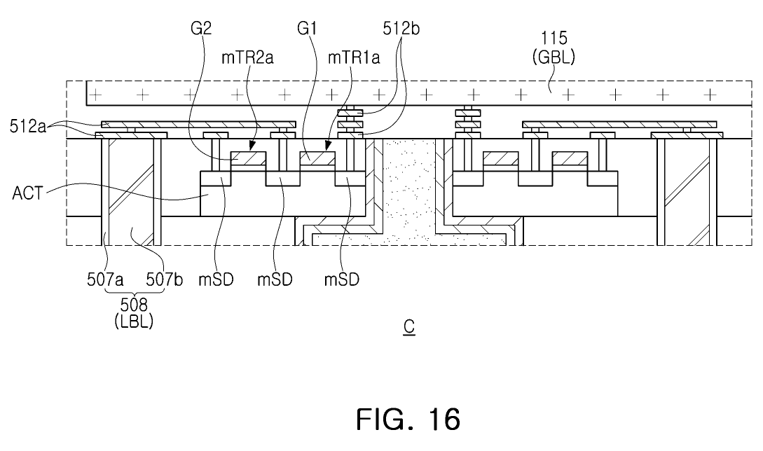

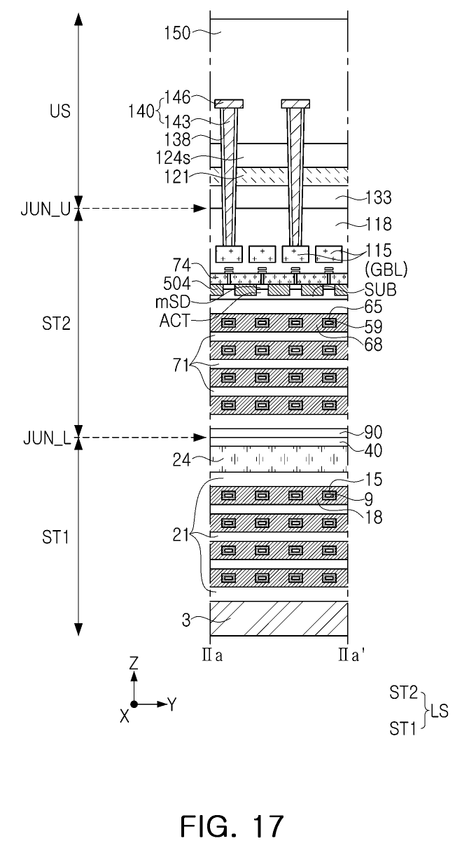

Referring to FIGS. 13, 14, 15, 16, and 17, examples of semiconductor devices according to an embodiment will be described. FIGS. 13, 14, 15, 16, and 17 are views illustrating examples of semiconductor devices according to an embodiment, wherein FIG. 13 is a view illustrating that upper multiplexers MUX_U are further included in the drawing of FIG. 3, FIG. 14 is a plan view illustrating some elements of a semiconductor device according to an embodiment, FIG. 15 is a cross-sectional view illustrating an area of FIG. 14, taken along line Ia-Ia’, FIG. 16 is a partial enlarged cross-sectional view illustrating an area indicated by ‘C’ of FIG. 15, and FIG. 17 is a cross-sectional view illustrating an area of FIG. 14, taken along line IIa-IIa’.

In an embodiment, referring to FIGS. 13, 14, 15, 16, and 17, the second structure ST2 described above may further include upper multiplexers MUX_U disposed on the upper insulating structure 71, a first routing interconnection structure 512a electrically connecting the upper multiplexers MUX_U and the local bit lines LBL, and a second routing interconnection structure 512b electrically connecting the upper multiplexers MUX_U and the global bit lines GBL.

The upper multiplexers MUX_U may each correspond to a corresponding global bit line GBL of the global bit lines GBL. For example, a first upper multiplexer MUX_U may be connected to a first global bit line GBL. As described above, each of the global bit lines GBL may be connected to N corresponding local bit lines LBL, and thus each of the global bit lines GBL may be connected to a corresponding upper multiplexer MUX_U and N corresponding local bit lines LBL. Therefore, the first upper multiplexer MUX_U may be connected to first N corresponding local bit lines LBL.

Each upper multiplexer MUX_U among the upper multiplexers MUX_U may include select transistors mTR1a that are each connected to a respective local bit line LBL of the N corresponding local bit lines LBL and precharge transistors mTR2a that are respectively connected to the select transistors mTR1a. Therefore, each upper multiplexer MUX_U connected to the N corresponding local bit lines LBL may include N select transistors mTR1a.

The transistors mTR1a and mTR2a of the upper multiplexers MUX_U may be disposed at a level higher than the second cell transistors cTR2. The transistors mTR1a and mTR2a of the upper multiplexers MUX_U may be disposed at a level lower than an upper surface of the second electrode 86 of the second data storage structure DS2.

At least some of the transistors mTR1a and mTR2a of the upper multiplexers MUX_U may vertically overlap the second cell transistors cTR2. A portion of the transistors mTR1a and mTR2a of the upper multiplexers MUX_U may vertically overlap the second data storage structure DS2.

Each of the transistors mTR1a and mTR2a of the upper multiplexers MUX_U may include source/drain regions mSD formed in an active region ACT, and gates G1 and G2 disposed on a channel region between the source/drain regions mSD. The active regions ACT may be disposed on a semiconductor substrate SUB, and may be defined by an element isolation region 504 on the semiconductor substrate SUB.

The select transistors mTR1a connected to the a corresponding global bit line GBL may electrically connect a selected local bit line among the local bit lines LBL to the global bit line GBL in response to a logic high state of a signal applied to select gate lines G1, and may electrically disconnect an unselected local bit line among the local bit lines LBL from the global bit line GBL in response to a logic low state of a signal applied to the select gate lines G1.

The precharge transistors mTR2a may connect corresponding local bit lines LBL to a precharge circuit (not illustrated) in response to a logic high state of an inversion signal of a signal applied to the select gate lines G1 to precharge gate lines G2. Therefore, the select transistors mTR1a of the upper multiplexers MUX_U may select the local bit lines LBL electrically connected to the global bit lines GBL.

Each of the select gate lines G1 and the precharge gate lines G2 may extend in the second horizontal direction (Y).

In the embodiment, since no voltage is applied to local bit lines LBL unselected by the upper multiplexers MUX_U, among the local bit lines LBL, parasitic capacitance between the unselected local bit lines LBL may be reduced. Therefore, the upper multiplexers MUX_U may prevent performance of the semiconductor device 1 from being degraded due to parasitic capacitance between the local bit lines LBL.

The local bit lines LBL may have the same configuration as the local bit lines (e.g., conductive pillar 108 of FIGS. 7A and 7B, conductive pillar 108’ of FIG. 9, conductive pillar 208 of FIGS. 10A and 10B, and conductive pillar 308 of FIG. 12) described above.

The upper multiplexers MUX_U may include first upper multiplexers MUX_U disposed at a level lower than of the first global bit lines GBL1, disposed at a level higher than the cell transistors cTR2 of the first upper memory cells MC2, and electrically connected to the first local bit lines LBL1 and the first global bit lines GBL1, and second upper multiplexers MUX_U disposed at a level lower than the second global bit lines GBL2, disposed at a level higher than the cell transistors cTR2 of the second upper memory cells MC2, and electrically connected to the second local bit lines LBL2 and the second global bit lines GBL2.

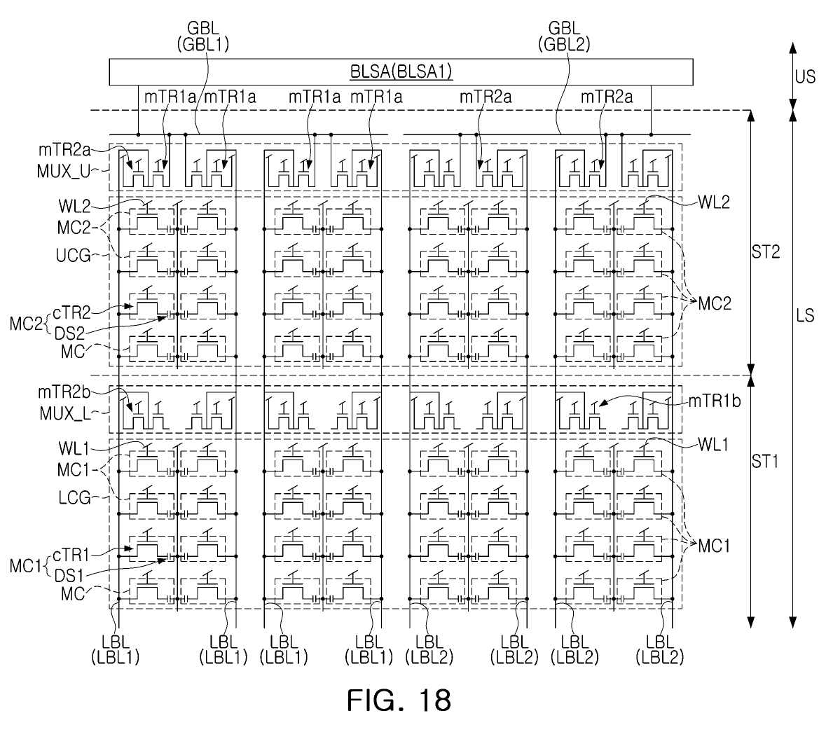

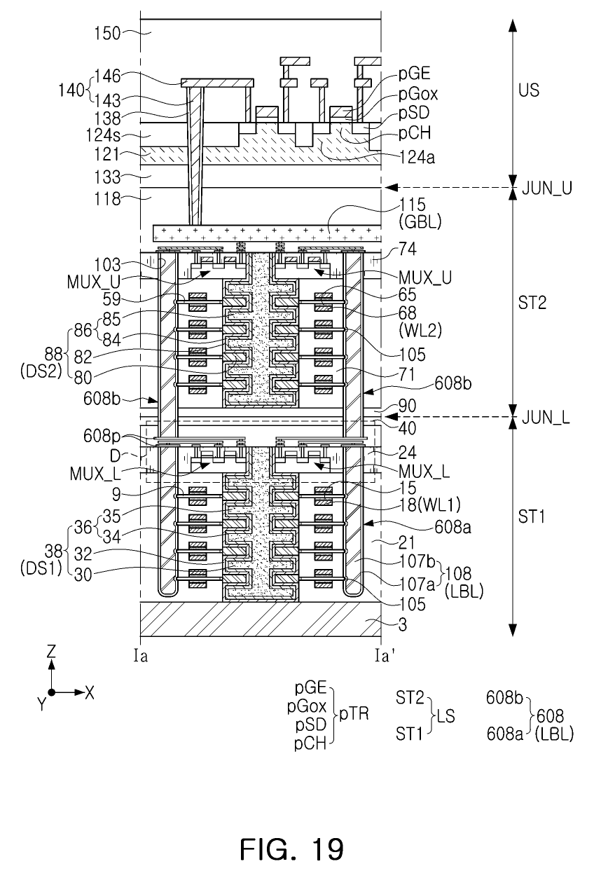

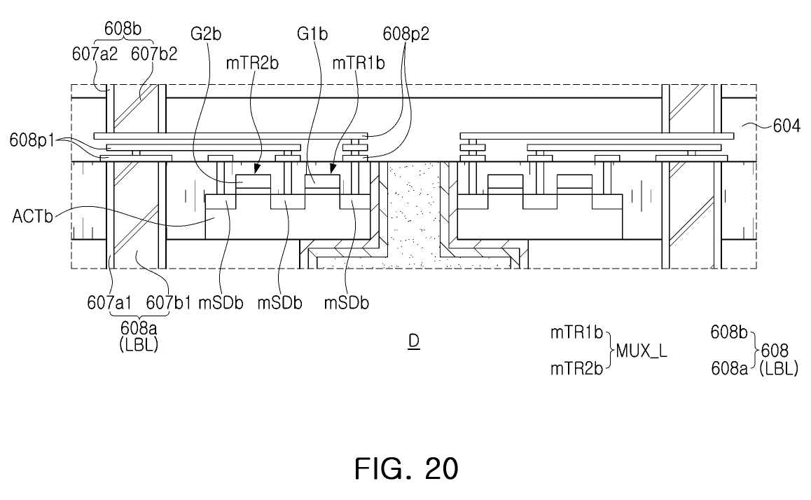

Referring to FIGS. 18, 19, and 20, an example of a semiconductor device according to an embodiment will be described. FIGS. 18, 19, and 20 are views illustrating examples of semiconductor devices according to an embodiment, wherein FIG. 18 is a view illustrating that lower multiplexers MUX_L are further included in the drawing of FIG. 13, FIG. 19 is a cross-sectional view illustrating an area of FIG. 14, taken along line Ia-Ia’, and FIG. 20 is a partial enlarged cross-sectional view illustrating an area indicated by ‘D’ of FIG. 19.

In an embodiment, referring to FIGS. 18, 19, and 20, the first structure ST1 described above may further include lower multiplexers MUX_L disposed on the lower insulating structure 21, a first lower routing interconnection structure 608p1 electrically connecting the lower multiplexers MUX_L and the local bit lines LBL, and a second lower routing interconnection structure 608p2 electrically connecting the lower multiplexers MUX_L and the local bit lines LBL.

The lower multiplexers MUX_L may include transistors that are the same or substantially the same as the upper multiplexers MUX_U. For example, each of the lower multiplexers MUX_L may include select transistors mTR1b each connected to N corresponding local bit lines LBL, and precharge transistors mTR2b each respectively connected to the select transistors mTR1b. Therefore, a first lower multiplexer MUX_L connected to first N corresponding local bit lines LBL may include N select transistors mTR1b.

The transistors mTR1b and mTR2b of the lower multiplexers MUX_L may be disposed at a level higher than the first cell transistors cTR1. The transistors mTR1b and mTR2b of the lower multiplexers MUX_L may be disposed at a level lower than an upper surface of the second electrode 36 of the first data storage structure DS1.

At least some of the transistors mTR1b and mTR2b of the lower multiplexers MUX_L may vertically overlap the first cell transistors cTR1. A portion of the transistors mTR1b and mTR2b of the lower multiplexers MUX_L may vertically overlap the first data storage structure DS1.

Each of the transistors mTR1b and mTR2b of the lower multiplexers MUX_L may include source/drain regions mSDb formed in an active region ACTb, and gates G1b and G2b disposed on a channel region between the source/drain regions mSDb.

In an embodiment, since no voltage is applied to local bit lines LBL unselected by the lower multiplexers MUX_L, among the local bit lines LBL, parasitic capacitance between the unselected local bit lines LBL may be reduced. Therefore, the lower multiplexers MUX_L may prevent performance of the semiconductor device 1 from being degraded due to parasitic capacitance between the local bit lines LBL.

Each of the local bit lines LBL may include a lower conductive pillar 608a connected to the first lower source/drain regions cSD1a of the corresponding lower memory cells MC1 among the lower memory cells MC1, and an upper conductive pillar 608b connected to the first upper source/drain regions cSD1b of the corresponding upper memory cells MC2 among the upper memory cells MC2.

The first lower routing interconnection structure 608p1 may electrically connect the lower multiplexers MUX_L and the lower conductive pillars 608a of the local bit lines LBL, and the second lower routing interconnection structure 608p2 may electrically connect the lower multiplexers MUX_L and the upper conductive pillars 608b of the local bit lines LBL.

The upper multiplexers MUX_U described in FIGS. 13 to 17 may be electrically connected to the upper conductive pillars 608b of the local bit lines LBL.

The lower multiplexers MUX_L may include first lower multiplexers MUX_L connected to the first local bit lines LBL1, disposed at a level higher than the cell transistors cTR1 of the first lower memory cells MC1, and vertically overlapping the first lower memory cells MC1, and second lower multiplexers MUX_L disposed at the same level as the first lower multiplexers MUX_L, connected to the second local bit lines LBL2, and vertically overlapping the second lower memory cells MC1.

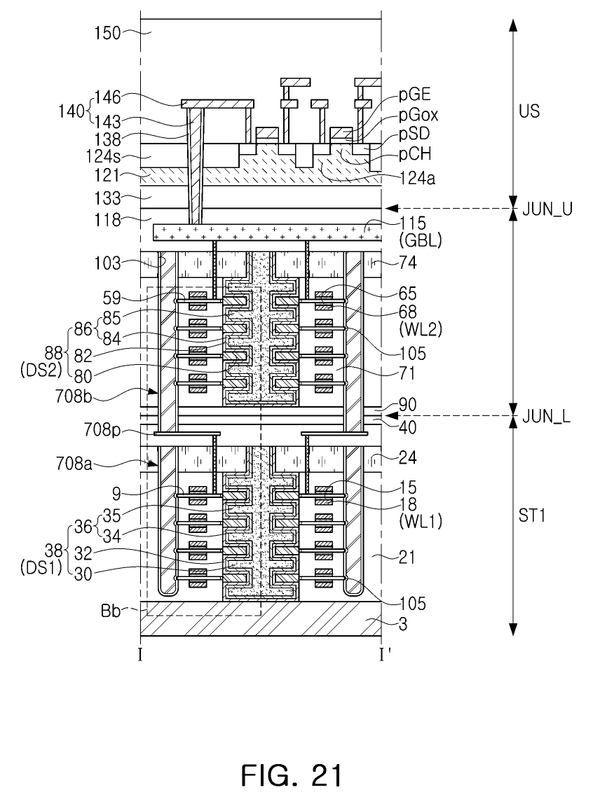

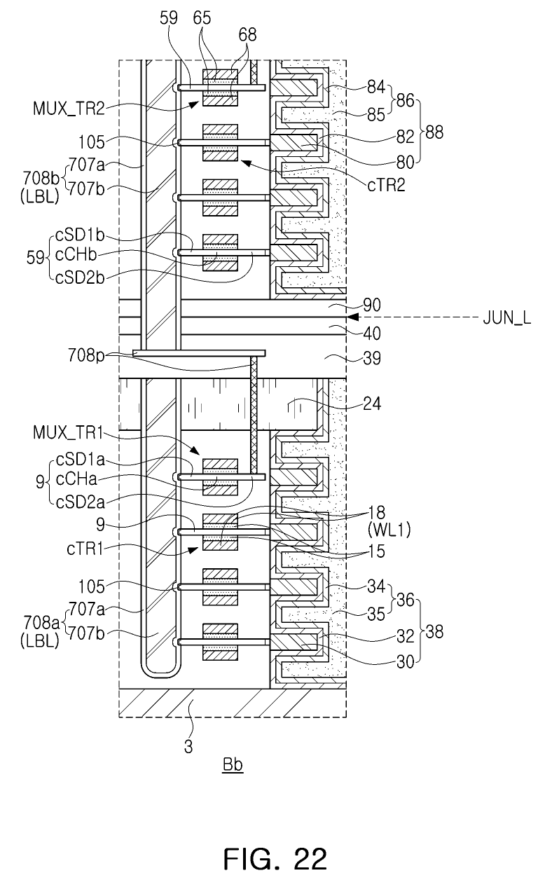

Referring to FIGS. 21 and 22, examples of semiconductor devices according to an embodiment will be described. FIG. 21 is a cross-sectional view illustrating an area of FIG. 6, taken along line I-I’, and FIG. 22 is a partial enlarged cross-sectional view illustrating an area indicated by ‘Bb’ of FIG. 21.

In an embodiment, referring to FIGS. 21 and 22, upper transistors among the second cell transistors cTR2 in FIGS. 7A and 7B may be replaced with upper select transistors MUX_TR2 of an upper multiplexer, and upper transistors among the first cell transistors cTR1 in FIGS. 7A and 7B may be replaced with lower select transistors MUX_TR1 of a lower multiplexer. The upper select transistors MUX_TR2 may be spaced apart from the second data storage structure DS2, and the lower select transistors MUX_TR1 may be spaced apart from the first data storage structure DS1. Each of the upper select transistors MUX_TR2 may have a size, different from a size of each of the cell transistors cTR1 and cTR2.

Each of the local bit lines LBL may include a lower conductive pillar 708a connected to side surfaces of the first lower source/drain regions cSD1a of corresponding lower memory cells MC1 among the lower memory cells MC1 and a side surface of a first source/drain region of the lower select transistor MUX_TR1, and an upper conductive pillar 708b connected to side surfaces of the first upper source/drain regions cSD1b of corresponding upper memory cells MC2 among the upper memory cells MC2 and a side surface of a first source/drain region of the upper select transistor MUX_TR2.

Each of the lower select transistors MUX_TR1 may have a size, different from a size of each of the cell transistors cTR1 and cTR2.

The first structure ST1 may further include a routing interconnection structure 708p electrically connecting the lower select transistors MUX_TR1 and the upper conductive pillars 708b.

Next, examples of a method for manufacturing a semiconductor device according to an embodiment will be described. In the method for manufacturing a semiconductor device according to an embodiment described below, a description of features that would be duplicative to that described above may be omitted.

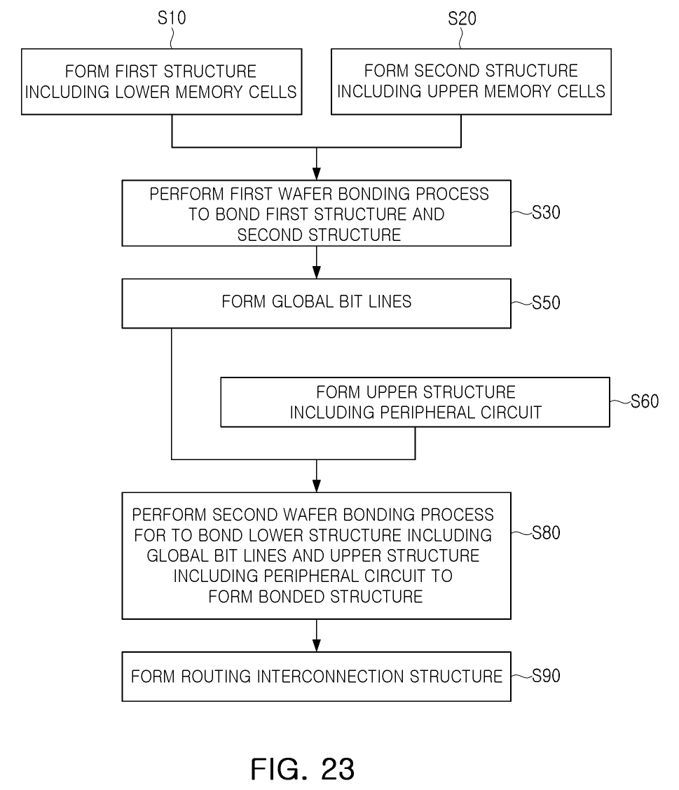

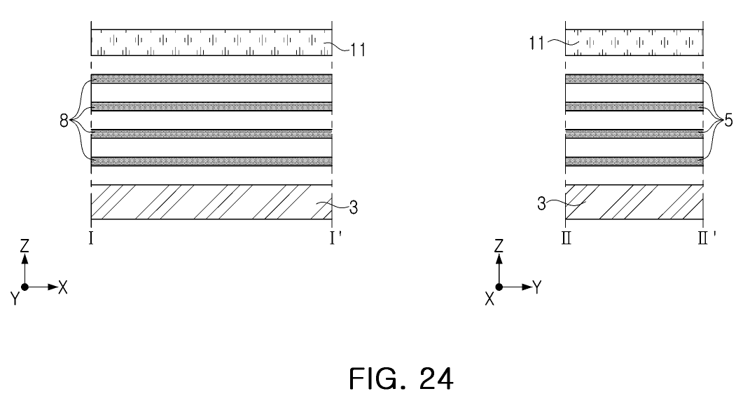

First, referring to FIGS. 23 to 30, and 31A to 31D, an example of a method for manufacturing a semiconductor device according to an embodiment will be described. In FIGS. 23 to 30, and 31A to 31D, FIG. 23 is a process flow diagram illustrating an example of a method for manufacturing a semiconductor device according to an embodiment, and FIGS. 24 to 30, and 31A to 31D are cross-sectional views illustrating an area of FIG. 6, taken along line I-I’ and an area of FIG. 6, taken along line II-II’.

Referring to FIG. 24, sacrificial semiconductor layers 5 and channel semiconductor layers 8, alternately and repeatedly stacked, may be formed on a base 3. The sacrificial semiconductor layers 5 may include a semiconductor material such as single-crystal SiGe or the like, and the channel semiconductor layers 8 may include a semiconductor material such as single-crystal Si or the like. An insulating layer 11 may be formed on a stack structure (5 and 8) including the sacrificial semiconductor layers 5 and the channel semiconductor layers 8.

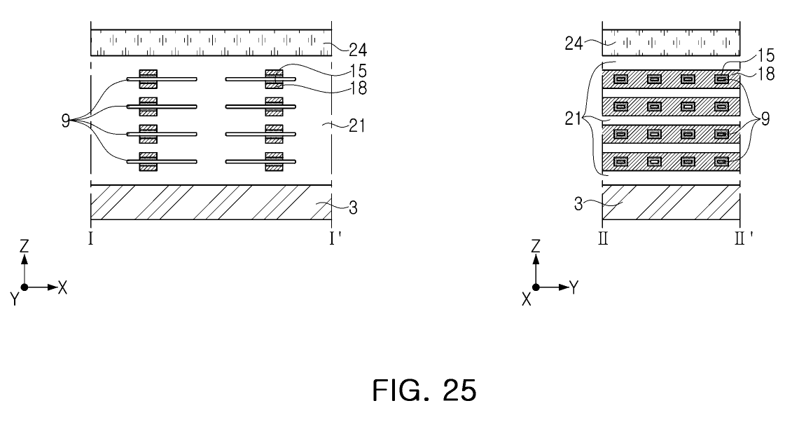

Referring to FIG. 25, the stack structure (5 and 8) may be patterned to form lower active patterns 9 in which the channel semiconductor layers 8 may be patterned. A structure buried by a lower insulating structure 21 and including lower cell gate electrodes 18 surrounding the lower active patterns 9, and lower cell gate dielectric layers 15 between the lower cell gate electrodes 18 and the lower active patterns 9, may be formed. First cell transistors cTR1 including the lower cell gate dielectric layers 15 and the lower cell gate electrodes 18, surrounding the lower active patterns 9, may be formed. A lower capping insulating layer 24 may be formed on the lower insulating structure 21.

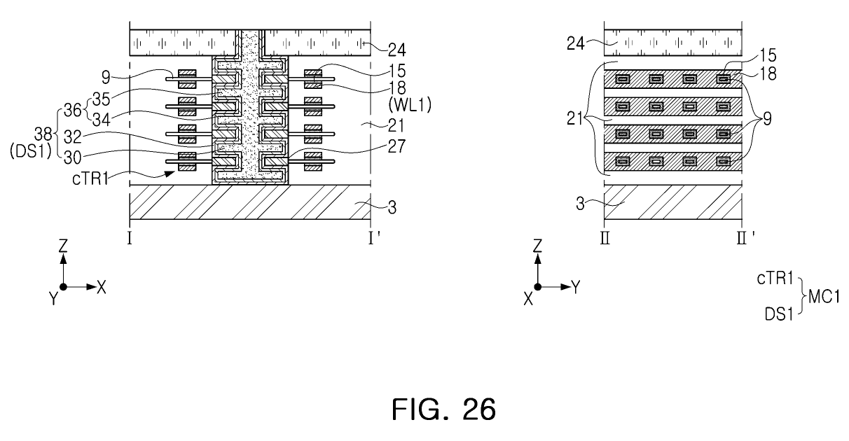

Referring to FIG. 26, first data storage structures DS1 connected to the first cell transistors cTR1 may be formed. The first data storage structures DS1 may penetrate through the lower capping insulating layer 24 and the lower insulating structure 21. Each of the first data storage structures DS1 may be a first data storage structure 38 including a first electrode 30 connected to a corresponding lower active pattern 9 among the lower active patterns 9, a second electrode 36 covering the first electrode 30, and a dielectric layer 32 between the first electrode 30 and the second electrode 36. The first cell transistors cTR1 and the first data storage structures DS1 may constitute lower memory cells MC1.

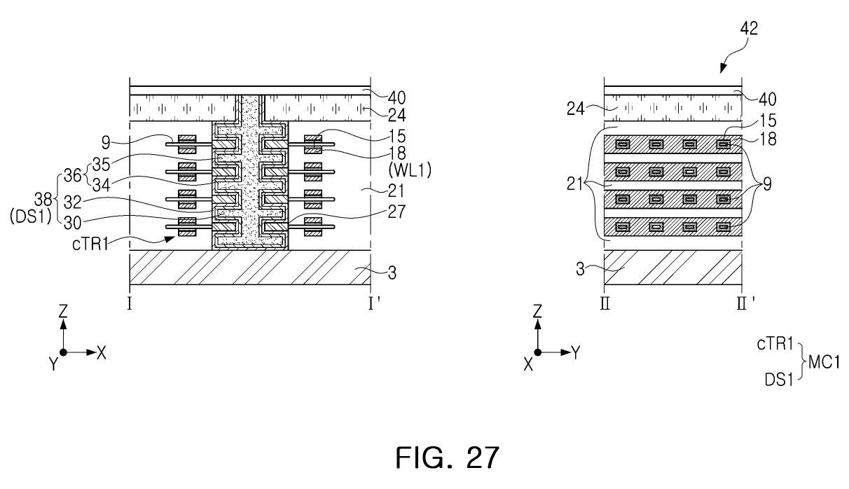

Referring to FIG. 23 and FIG. 27, a first insulating layer 40 may be formed on the lower capping insulating layer 24 and the first data storage structures DS1. Therefore, a first structure 42 including the lower memory cells MC1 may be formed (S10).

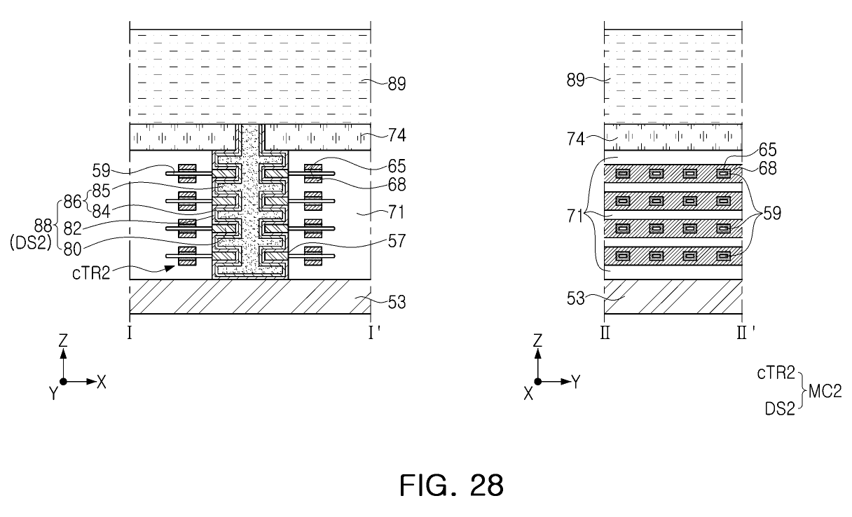

Referring to FIG. 28, by performing the same method as described in FIGS. 23 to 26, upper memory cells MC2, upper capping insulating layer 74, a substrate 53, and upper insulating structure 71, corresponding to the lower memory cells MC1, the lower capping insulating layer 24, the base 3, and the lower insulating structure 21, described in FIG. 26, respectively, may be formed. Each of the upper memory cells MC2 may include second cell transistors cTR2 and a second data storage structure DS2, corresponding to the first cell transistor cTR1 and the first data storage structure DS1, respectively. A carrier 89 may be formed on the upper capping insulating layer 74.

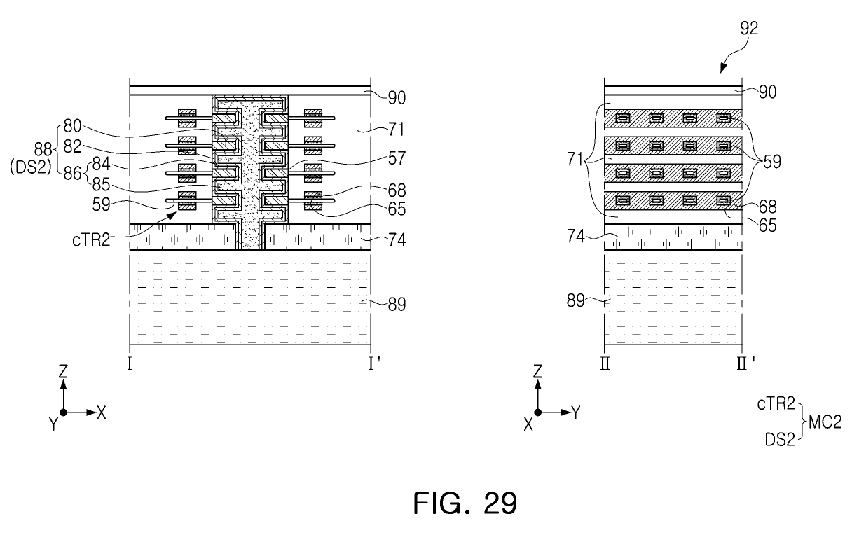

Referring to FIGS. 23 and 29, after removing the substrate 53, a second insulating layer 90 may be formed on the upper insulating structure 71 and the second data storage structure DS2. Therefore, a second structure 92 including the upper memory cells MC2 may be formed (S20).

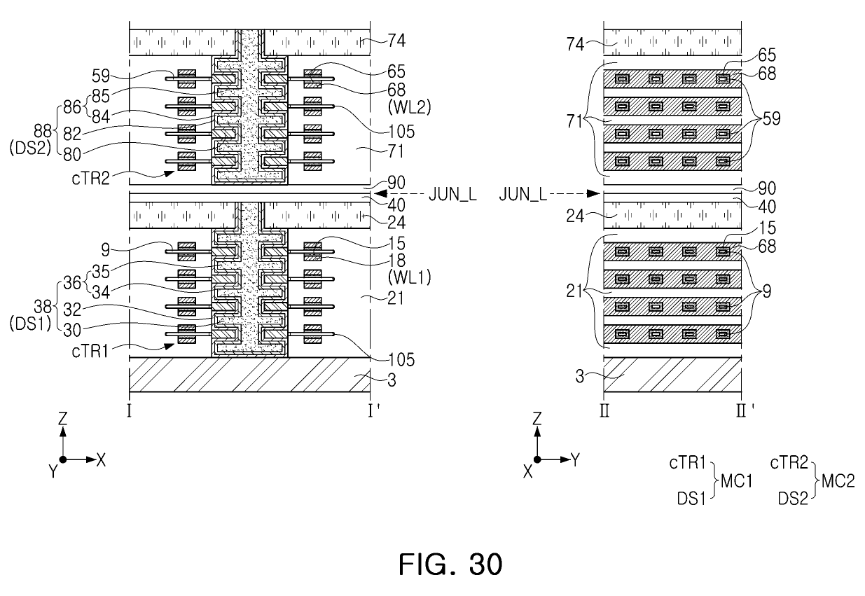

Referring to FIG. 23 and FIG. 30, a first wafer bonding process for bonding the first and second structures (42 of FIG. 27, and 92 of FIG. 29) may be performed (S30). By the first wafer bonding process, the first insulating layer 40 and the second insulating layer 90 may be bonded to form a first bonded region JUN_L between the first insulating layer 40 and the second insulating layer 90. After the first wafer bonding process, the carrier 89 may be removed.

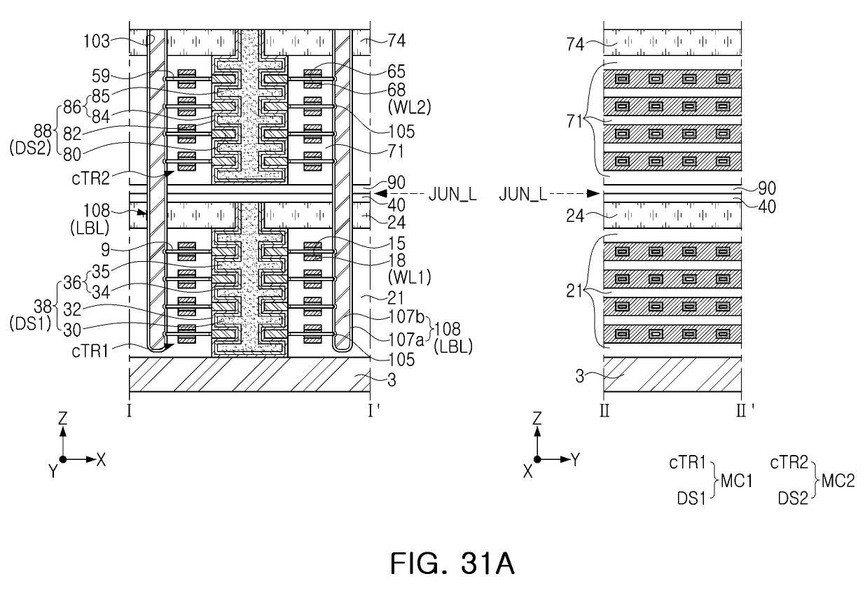

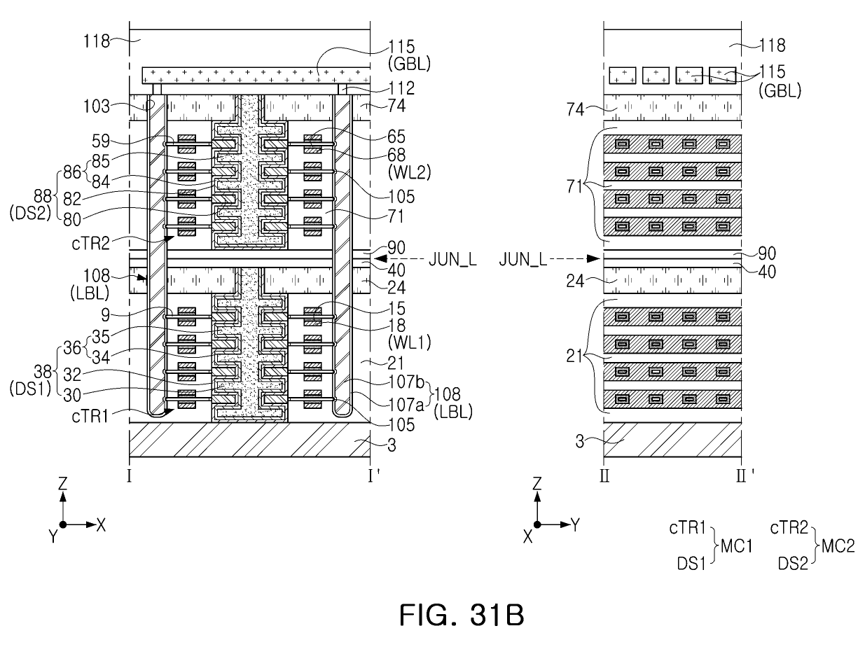

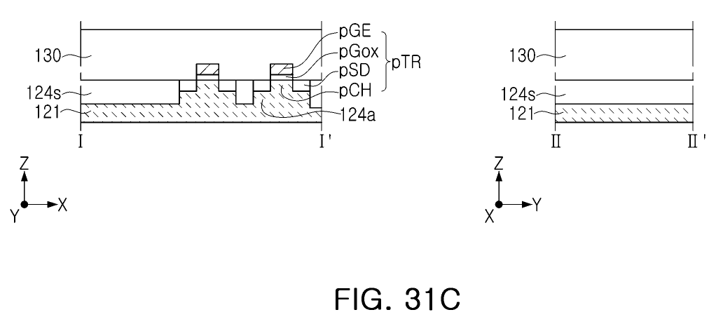

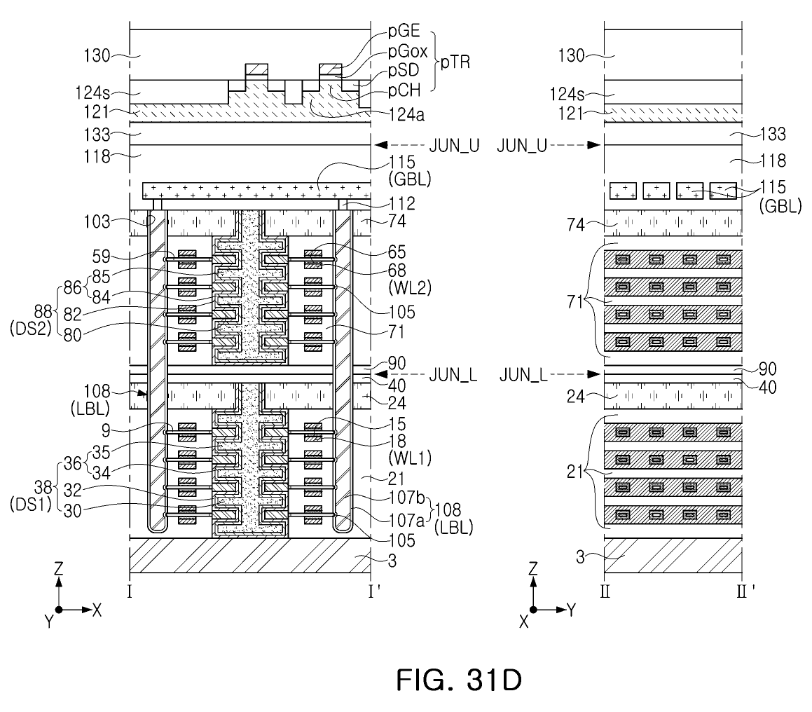

Referring to FIG. 31A, holes 103 penetrating through the upper capping insulating layer 74, the upper insulating structure 71, the first and second insulating layers 40 and 90, and the lower capping insulating layer 24 and extending into the lower insulating structure 21, may be formed, and metal-semiconductor compound layers (105 of FIG. 7B) may be formed on surfaces of the lower and upper active patterns 9 and 59 exposed by the holes 103, and local bit lines LBL may be formed in the holes 103. The local bit lines LBL may be conductive pillars 108 penetrating through the upper capping insulating layer 74, the upper insulating structure 71, the first and second insulating layers 40 and 90, the first bonded region JUN_L, the lower capping insulating layer 24, and extending into the lower insulating structure 21. Each of the conductive pillars 108 may include a pillar pattern 107b and a conductive liner 107a covering side and lower surfaces of the pillar pattern 107b.

Referring to FIGS. 23 and 31B, global bit lines GBL may be formed (S50). Forming the global bit lines GBL may include forming contact plugs 112 to which the local bit lines LBL are connected, on the local bit lines LBL, and forming the global bit lines GBL on the contact plugs 112. The global bit lines GBL may be embedded in the third insulating layer 118.

Referring to FIG. 23 and FIG. 31C, an upper structure including a peripheral circuit may be formed (S60). The peripheral circuit may include peripheral transistors pTR that may configure bit line sense amplifiers. Each of the peripheral transistors pTR may include peripheral source/drain regions pSD disposed in a peripheral active region 124a, a peripheral channel region pCH between the peripheral source/drain regions pSD, a peripheral gate electrode pGE on the peripheral channel region pCH, and a peripheral gate dielectric layer pGox between the peripheral gate electrode pGE and the peripheral channel region pCH. The peripheral active region 124a may be defined by a device isolation region 124s disposed on the substrate 121. The peripheral transistors pTR may be covered by an insulating layer 130 on the substrate 121.

Referring to FIGS. 23 and 31D, a fourth insulating layer 133 may be formed below the substrate 121. A second wafer bonding process for bonding the lower structure including the global bit lines GBL and an upper structure including the peripheral circuit may be performed to form a bonded structure (S80). For example, the fourth insulating layer 133 below the substrate 121 may be bonded to the third insulating layer 118 covering the global bit lines GBL to form a second bonded region JUN_U between the third and fourth insulating layers 118 and 133.

Again, referring to FIG. 23 together with FIGS. 5, 6, 7A, 7B, and 8, a routing interconnection structure 140 may be formed (S90). The routing interconnection structure 140 may include a through-electrode 143 penetrating through the substrate 121, and a connecting interconnection 146 electrically connecting the through-electrode 143 and the peripheral transistor pTR on the substrate 121. The through-electrode 143 may be spaced apart from the substrate 121 by an insulating spacer 138 on a side surface of the through-electrode 143. Subsequently, an upper insulating structure 150 covering the peripheral transistor pTR and the routing interconnection structure 140 may be formed.

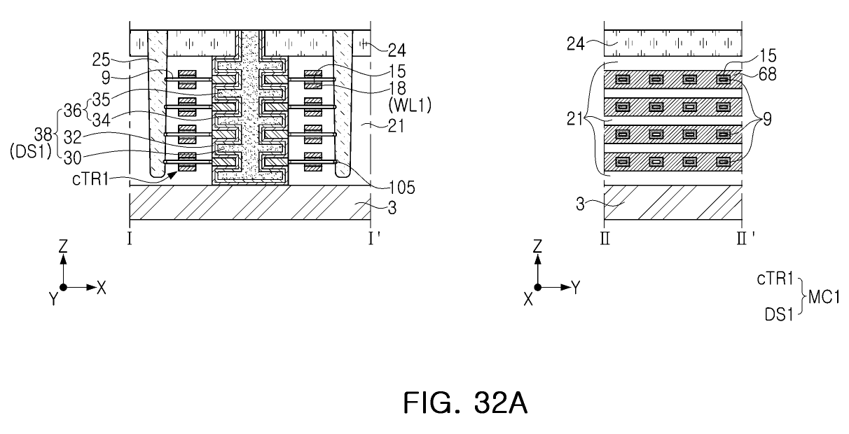

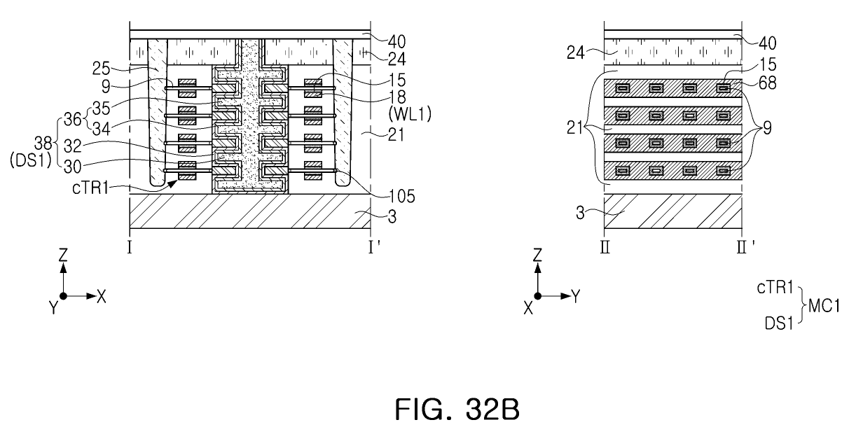

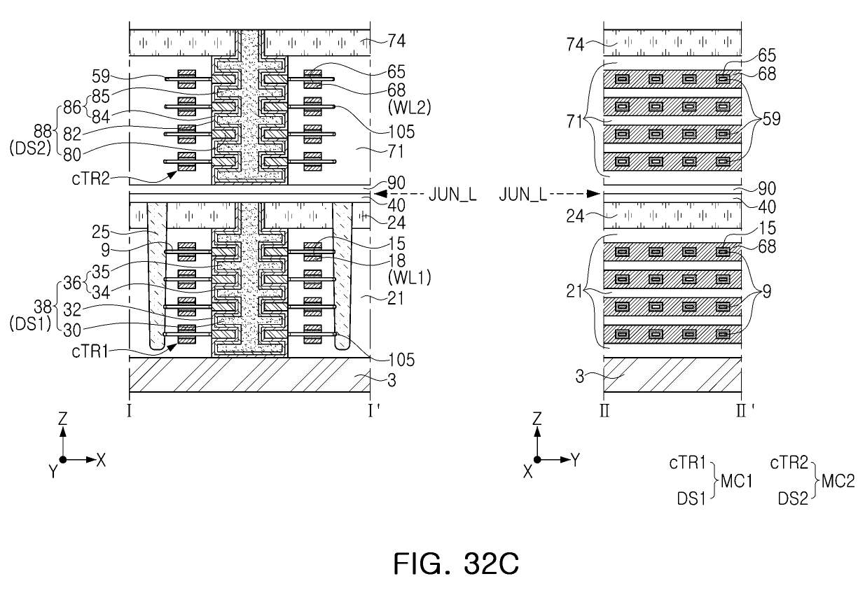

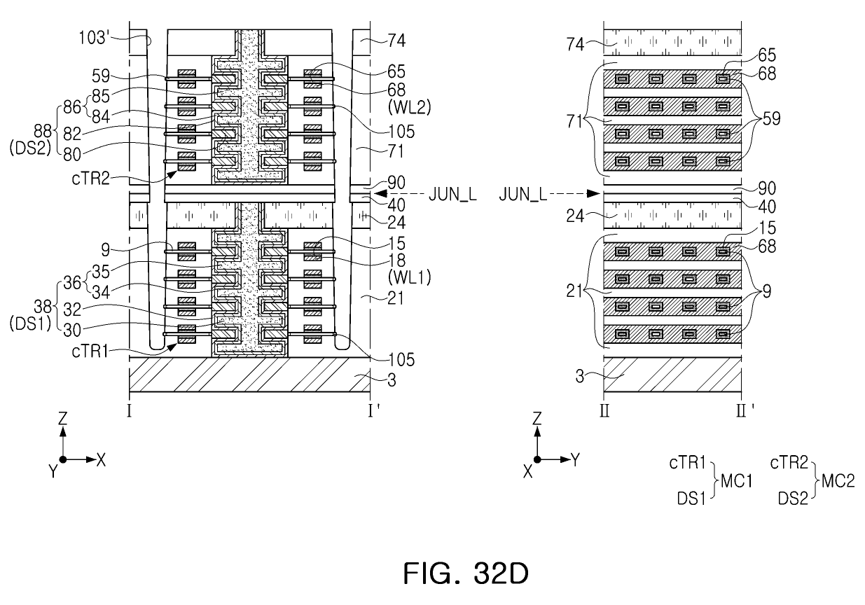

Next, referring to FIGS. 32A to 32D, an example of a method for manufacturing a semiconductor device according to an embodiment will be described. FIGS. 32A to 32D are cross-sectional views illustrating an area of FIG. 6, taken along line I-I’ and an area of FIG. 6, taken along line II-II’.

Referring to FIG. 32A, in results as in FIG. 26, sacrificial contact plugs 25 penetrating through the lower capping insulating layer 24 and extending into the insulating structure 21, to be connected to the lower active patterns 9, may be formed.

Referring to FIG. 32B, the first insulating layer 40 as described in FIG. 27 may be formed on the lower capping insulating layer 24 and the sacrificial contact plugs 25.

Referring to FIG. 32C, the second insulating layer (90 of FIG. 29) of the second structure (92) as described in FIG. 29 may be bonded to the first insulating layer 40, to form the first bonded region JUN_L as described in FIG. 30.

Referring to FIG. 32D, holes passing through the upper capping insulating layer 74, the upper insulating structure 71, the second insulating layer 90, the first bonded region JUN_L, and the first insulating layer 40, and exposing the sacrificial contact plugs 25 may be formed, and the sacrificial contact plugs 25 exposed by the holes may be removed to form bit line holes 103’. Metal-semiconductor compound layers (105 in FIG. 7B) may be formed on surfaces of the lower and upper active patterns 9 and 59 exposed by the holes 103’, and local bit lines LBL may be formed in the holes 103’. The local bit lines LBL formed in the holes 103’ may be conductive pillars 108’ as in FIG. 9.

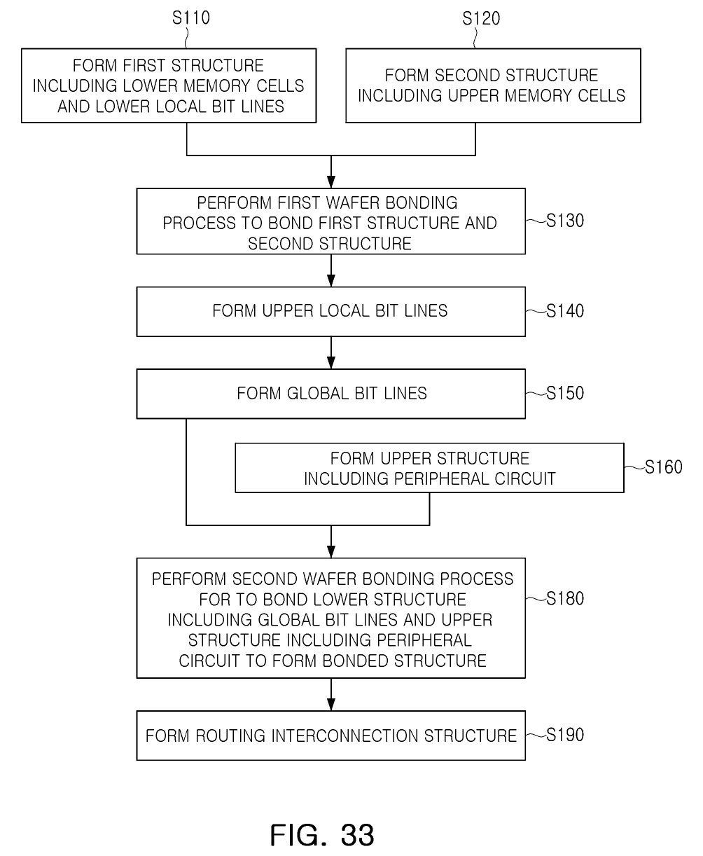

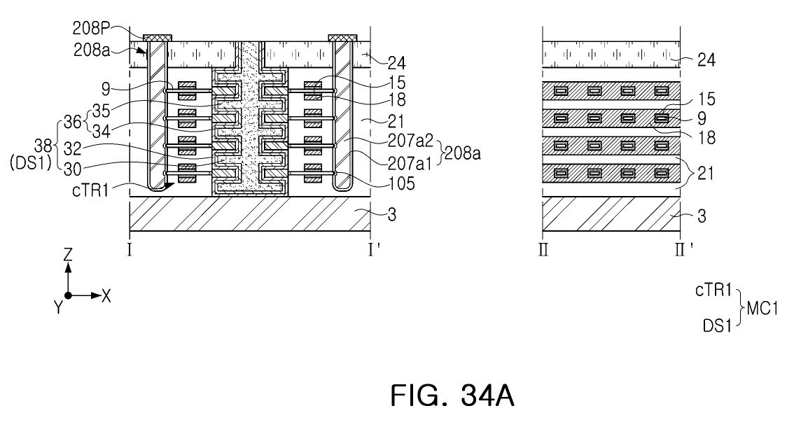

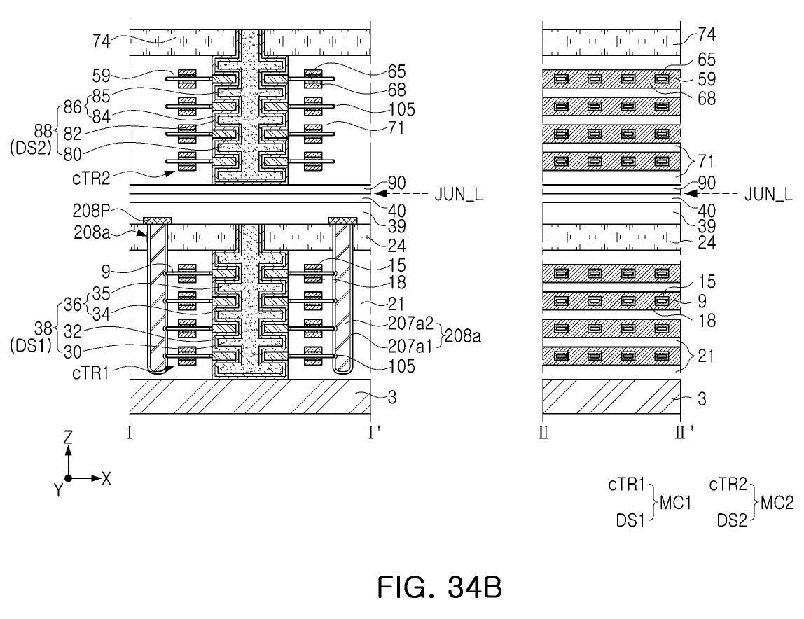

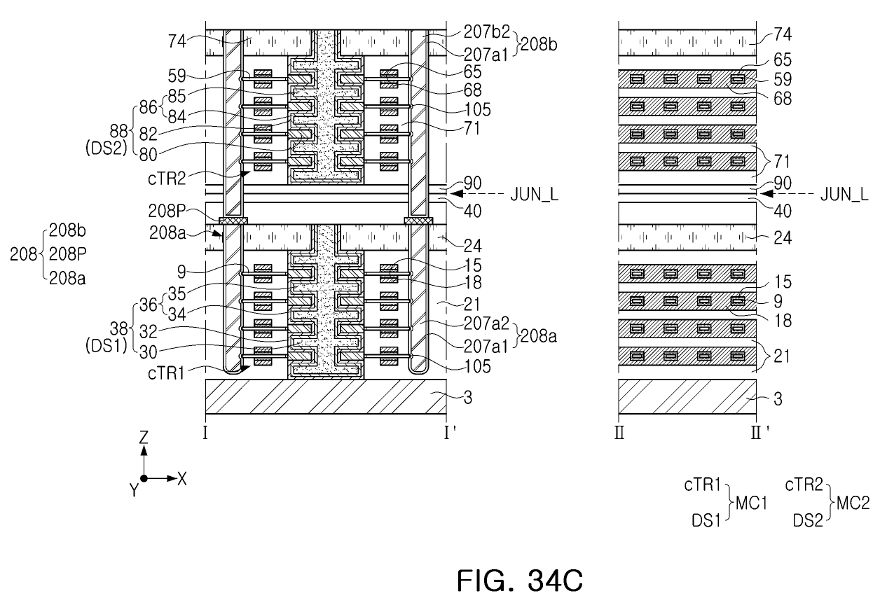

Next, an example of a method for manufacturing a semiconductor device according to an embodiment will be described with reference to FIGS. 33 and 34A to 34C. FIG. 33 is a process flow diagram illustrating an example of a method for manufacturing a semiconductor device according to an embodiment, and FIGS. 34A to 34C are cross-sectional views illustrating an area of FIG. 6, taken along line I-I’, and an area of FIG. 6, taken along line II-II’.

Referring to FIGS. 33 and 34A, a first structure including lower memory cells MC1 and lower local bit lines LBL (e.g., lower conductive pillars 208a) may be formed (S110). After forming the lower memory cells MC1 using the method described above, the lower conductive pillars 208a passing through a lower capping insulating layer 24, extending downward, and connected to the lower memory cells MC1, may be formed, and landing pads 208P may be formed on the lower conductive pillars 208a.

Referring to FIGS. 33 and 34B, a second structure including upper memory cells MC2 may be formed (S120). An interlayer insulating layer 39 covering the landing pads 208P in FIG. 34A, and a first insulating layer 40 on the interlayer insulating layer 39 may be formed. The second structure may be a structure formed to reach the upper memory cells MC2 and the second insulating layer 90 as in FIG. 29.

A first wafer bonding process for bonding the first and second structures may be performed (S130). Therefore, the first insulating layer 40 and the second insulating layer 90 may be bonded to form a first bonded region JUN_L.

Referring to FIG. 33 and FIG. 34C, upper local bit lines (e.g., upper conductive pillar 208b) may be formed (S140). The upper local bit lines may be connected to the upper memory cells MC2, and may be connected to the landing pads 208P. Therefore, local bit lines LBL including the lower conductive pillars 208a, the landing pads 208P, and the upper conductive pillars 208b as described in FIGS. 10A and 10B may be formed.

Referring again to FIG. 33 together with FIGS. 10A, 10B, and 11, in the same manner to that described in FIG. 23, global bit lines GBL may be formed (S150), an upper structure including a peripheral circuit may be formed (S160), and a second wafer bonding process for bonding a lower structure including the global bit lines GBL and the upper structure including the peripheral circuit may be performed to form a bonded structure (S180), and a routing interconnection structure 140 may be formed (S190).

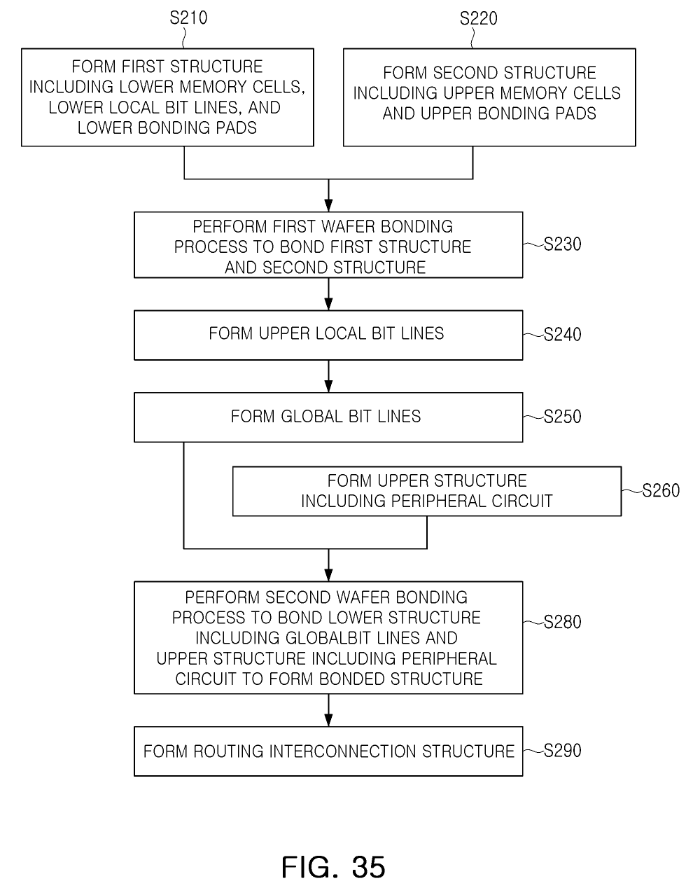

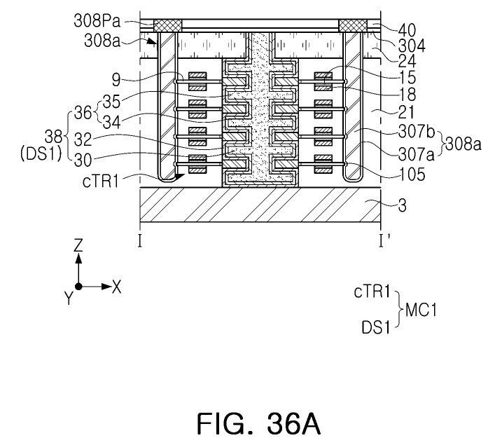

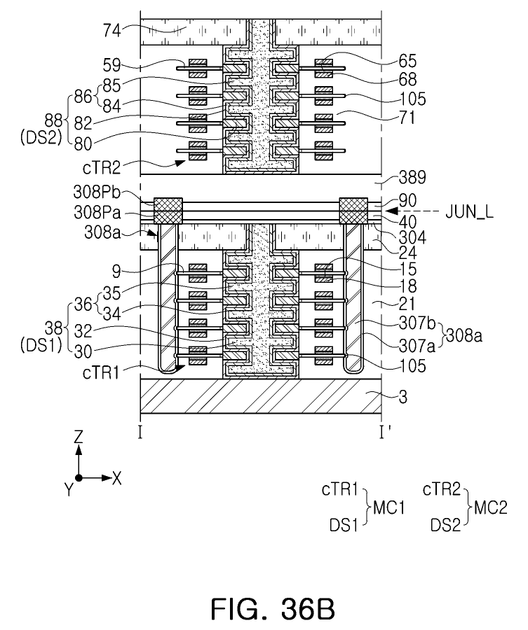

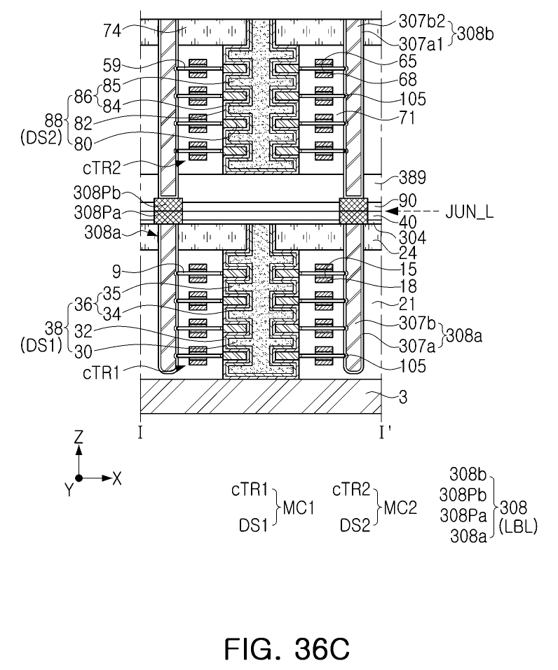

Next, an example of a method for manufacturing a semiconductor device according to an embodiment will be described with reference to FIGS. 35 and 36A to 36C. FIG. 35 is a process flow diagram illustrating an example of a method for manufacturing a semiconductor device according to an embodiment, and FIGS. 36A to 36C are cross-sectional views illustrating an area of FIG. 6, taken along line I-I’, and an area of FIG. 6, taken along line II-II’.

Referring to FIGS. 35 and 36A, a first structure including lower memory cells MC1, lower local bit lines (e.g., lower conductive pillars 308a), and lower bonding pads 308Pa may be formed (S210). After forming the lower memory cells MC1 using the method described above, the lower conductive pillars 308a passing through a lower capping insulating layer 24, extending downward, and connected to the lower memory cells MC1, may be formed, an interlayer insulating layer 304 covering the lower conductive pillars 308a may be formed, a first insulating layer 40 covering the interlayer insulating layer 304 may be formed, and the lower bonding pads 308Pa connected to the lower conductive pillars 308a may be formed. Upper surfaces of the lower bonding pads 308Pa may be coplanar with an upper surface of the first insulating layer 40.

Referring to FIG. 35 and FIG. 36B, a second structure including upper memory cells MC2 and upper bonding pads 308Pb may be formed (S220). The second structure may be a structure in which, after forming the upper memory cells MC2 as in FIG. 29, an interlayer insulating layer 389 is formed, a second insulating layer 90 covering the interlayer insulating layer 389 is formed, and the upper bonding pads 308Pb having exposed surfaces, coplanar with exposed surfaces of the second insulating layer 90, is formed.

A first wafer bonding process for bonding the first and second structures may be performed (S230). Therefore, the first insulating layer 40 and the second insulating layer 90 may be bonded, and the lower bonding pads 308Pa and the upper bonding pads 308Pb may be bonded, to form a first bonded region JUN_L.

Referring to FIG. 35 and FIG. 36C, upper local bit lines LBL may be formed (S240). The upper local bit lines LBL (e.g., upper conductive pillars 308b) may be connected to the upper memory cells MC2, and may be connected to the upper bonding pads 308Pb. Therefore, local bit lines LBL including the lower conductive pillars 308a, the lower and upper bonding pads 308Pa and 308Pb, and the upper conductive pillars 308b as described in FIG. 12 may be formed.

Again, referring to FIG. 35 together with FIG. 12, in the same manner to that described in FIG. 23, global bit lines GBL may be formed (S250), an upper structure including a peripheral circuit may be formed (S260), a second wafer bonding process for bonding a lower structure including the global bit lines GBL and the upper structure including the peripheral circuit may be performed to form a bonded structure (S280), and a routing interconnection structure 240 may be formed (S290).

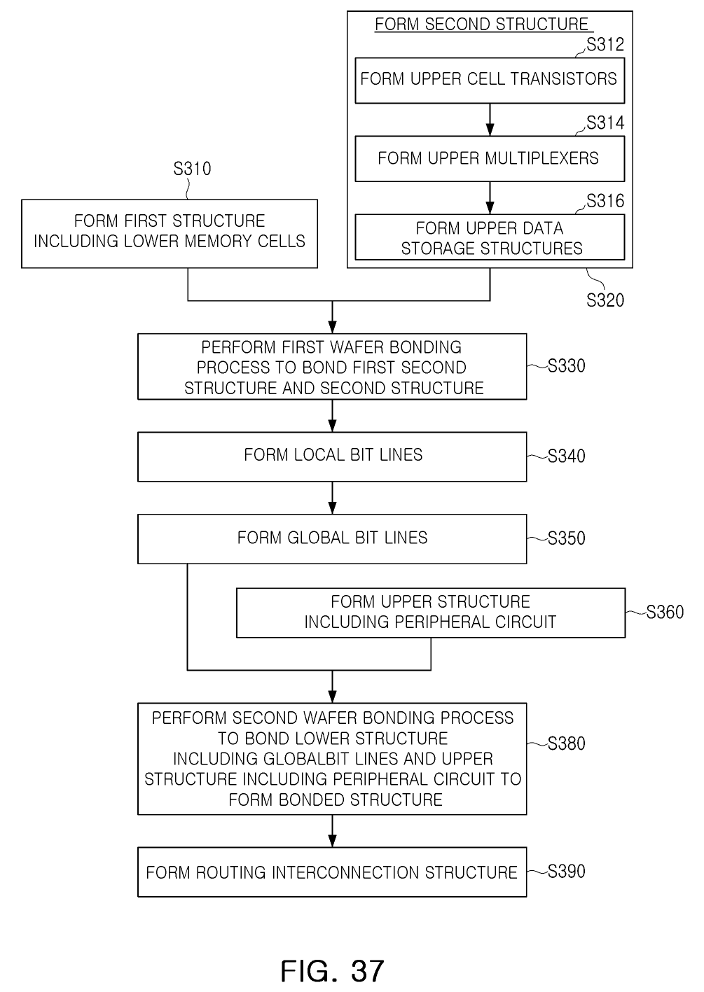

Next, referring to FIG. 37, an example of a manufacturing method for a semiconductor device described with reference to FIGS. 13 to 17 will be described. FIG. 37 is a process flow diagram illustrating an example of a semiconductor device manufacturing method according to an embodiment.

Referring to FIG. 37 together with FIGS. 13 to 17, a first structure including lower memory cells MC1 may be formed (S310). A second structure may be formed (S320). The formation of the second structure may include forming upper cell transistors cTR2 (S312), forming upper multiplexers MUX_U (S314), and forming upper data storage structures DS2 (S316). The upper cell transistors cTR2 and the upper data storage structures DS2 may form upper memory cells MC2.

A first wafer bonding process for bonding the first and second structures may be performed (S330). A first bonded region JUN_L may be formed by the first wafer bonding process. Local bit lines LBL may be formed (S340). The local bit lines LBL may be connected to the lower and upper memory cells MC1 and MC2.

Global bit lines GBL may be formed (S350). Before forming the global bit lines GBL, a first routing interconnection structure 512a electrically connecting the upper multiplexers MUX_U and the local bit lines LBL, and a second routing interconnection structure 512b electrically connecting the upper multiplexers MUX_U and the global bit lines GBL may be formed.

In the same manner to that described in FIG. 23, an upper structure including a peripheral circuit may be formed (S360), and a second wafer bonding process for bonding a lower structure including the global bit lines GBL and the upper structure including the peripheral circuit may be performed to form a bonded structure (S380), and a routing interconnection structure 240 may be formed (S390).

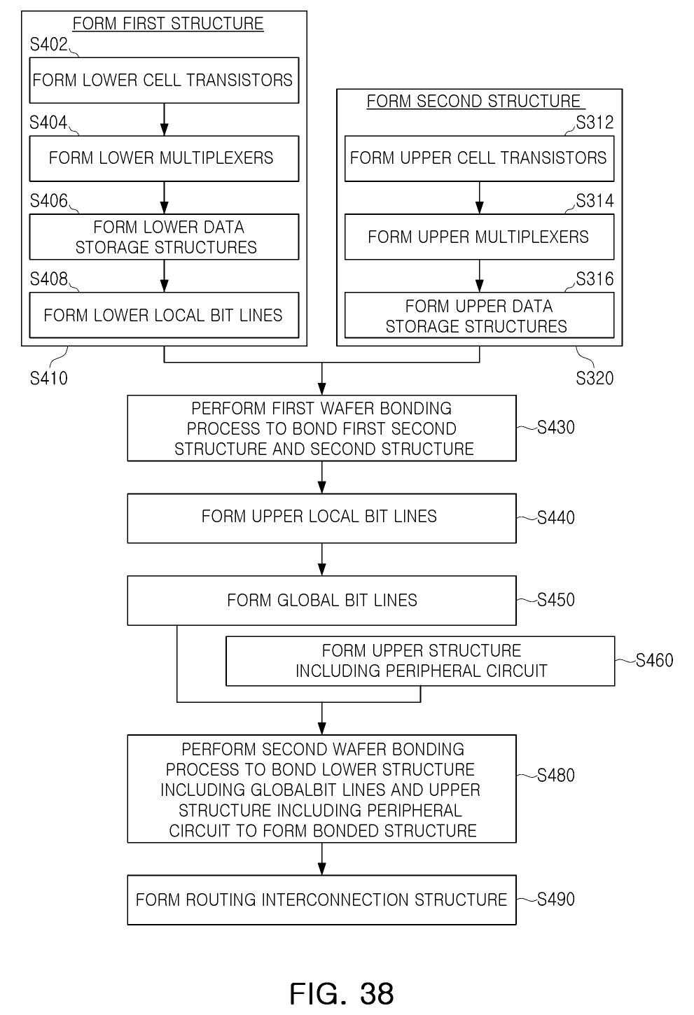

Next, referring to FIG. 38, an example of a manufacturing method for a semiconductor device described with reference to FIGS. 18 to 20 will be described. FIG. 38 is a process flow diagram illustrating an example of a method for manufacturing a semiconductor device according to an embodiment.

Referring to FIG. 38 together with FIGS. 18 to 20, a first structure may be formed (S410). The formation of the first structure may include forming lower cell transistors cTR1 (S402), forming lower multiplexers MUX_L (S404), forming lower data storage structures DS1 (S406), and forming lower local bit lines LBL (e.g., lower conductive pillars 608a) (S408). The lower cell transistors cTR1 and the lower data storage structures DS1 may form lower memory cells MC2. The lower conductive pillars 608a may be connected to the lower memory cells MC2. The formation of the first structure may further include forming routing interconnection structures 608p1 and 608p2 electrically connected to the lower multiplexers MUX_L.

The second structure may be formed (S320) in the same manner to that described in FIG. 37. The formation of the second structure may include forming upper cell transistors cTR2 (S312), forming upper multiplexers MUX_U (S314), and forming upper data storage structures DS2 (S316). The upper cell transistors cTR2 and the upper data storage structures DS2 may form upper memory cells MC2.

A first wafer bonding process for bonding the first and second structures may be performed (S430). A first bonded region JUN_L may be formed by the first wafer bonding process.

Upper local bit lines LBL (e.g., upper conductive pillars 608b) may be formed (S440). The upper conductive pillars 608b may be electrically connected to the upper memory cells MC2 and the routing interconnection structure 608p2.

Global bit lines GBL may be formed (S450). Before forming the global bit lines GBL, a first routing interconnection structure 512a electrically connecting the upper multiplexers MUX_U and the local bit lines LBL, and a second routing interconnection structure 512b electrically connecting the upper multiplexers MUX_U and the global bit lines GBL may be formed.

In the same manner to that described in FIG. 23, an upper structure including a peripheral circuit may be formed (S460), and a second wafer bonding process for bonding a lower structure including the global bit lines GBL and the upper structure including the peripheral circuit may be performed to form a bonded structure (S480), and a routing interconnection structure 240 may be formed (S490).

According to embodiments, a first structure including lower memory cells arranged three-dimensionally and a second structure including upper memory cells arranged three-dimensionally may be bonded by a wafer bonding process, and local bit lines may then be formed. Therefore, a degree of integration of a semiconductor device may increase.

According to embodiments, a global bit line may be disposed between a sense amplifier and local bit lines to improve performance of a semiconductor device.

Various advantages and effects of the present inventive concept are not limited to the above-described contents, and will be more easily understood in the process of describing specific embodiments.

While example embodiments have been illustrated and described above, it will be apparent to those skilled in the art that modifications and variations could be formed without departing from the scope of the present inventive concept as defined by the appended claims.

What is claimed is:

1. A semiconductor device comprising:
a lower structure including a first structure and a second structure on the first structure; and
an upper structure disposed on the lower structure and including a peripheral circuit,
wherein the first structure includes lower memory cells arranged three-dimensionally along a vertical direction, a first horizontal direction, and a second horizontal direction, which are perpendicular to one another,
the second structure includes upper memory cells vertically overlapping the lower memory cells and arranged three-dimensionally along the vertical direction, the first horizontal direction, and the second horizontal direction,
the lower structure further includes a first local bit line, a second local bit line, a third local bit line, and a fourth local bit line, with a first side surface of the first local bit line connected to a first memory cell group of the lower and upper memory cells, a second side surface of the second local bit line connected to a second memory cell group of the lower and upper memory cells, a third side surface of the third local bit line connected to a third memory cell group of the lower and upper memory cells, and a fourth side surface of the fourth local bit line connected to a fourth memory cell group of the lower and upper memory cells,
the second structure further includes a first global bit line and a second global bit line, and
the first global bit line is connected to the first local bit line and the second local bit line and the second global bit line is connected to the third local bit line and the fourth local bit line.

2. The semiconductor device of claim 1, wherein the peripheral circuit includes a bit line sense amplifier connected to the first and second global bit lines, and
the upper structure further includes a routing interconnection structure electrically connecting the bit line sense amplifier and the first and second global bit lines.

3. The semiconductor device of claim 1, wherein each of the lower memory cells and the upper memory cells includes a cell transistor and a data storage structure connected to the cell transistor,
wherein each of the cell transistors includes:
a first source/drain region and a second source/drain region spaced apart from each other in the first horizontal direction;
a channel region between the first source/drain region and the second source/drain region;
a cell gate electrode vertically overlapping the channel region and extending in the second horizontal direction; and
a cell gate dielectric layer between the cell gate electrode and the channel region,
wherein the first side surface of the first local bit line is connected to each first source/drain region of the cell transistors of the first memory cell group of lower and upper memory cells, and
wherein the second side surface of the second local bit line is connected to each first source/drain regions of the cell transistors of the second memory cell group of the lower and upper memory cells.

4. The semiconductor device of claim 1, wherein the first local bit line and the second local bit line are sequentially arranged in the first horizontal direction, and
the third local bit line and the fourth local bit line are sequentially arranged in the first horizontal direction.

5. The semiconductor device of claim 1, wherein the first local bit line is a conductive pillar extending from a level lower than a channel region of a cell transistor of a lowermost memory cell among the lower memory cells to a level higher than a channel region of a cell transistor of an uppermost memory cell among the upper memory cells.

6. The semiconductor device of claim 5, wherein a side surface of the conductive pillar of the first local bit line has a bend portion at a level lower than a bonded region between the first structure and the second structure and higher than a cell transistor of an uppermost memory cell among the lower memory cells.

7. The semiconductor device of claim 1, wherein the first local bit line includes:
a lower conductive pillar connected to the lower memory cells of the first memory cell group;
an upper conductive pillar connected to the upper memory cells of the first memory cell group; and
a landing pad between the lower conductive pillar and the upper conductive pillar.

8. The semiconductor device of claim 7, wherein the landing pad is in contact with an upper surface of the lower conductive pillar and a lower surface of the upper conductive pillar.

9. The semiconductor device of claim 8, wherein the landing pad is disposed at a level higher than an uppermost lower memory cell among the lower memory cells and at a level lower than a lowermost upper memory cell among the upper memory cells.

10. The semiconductor device of claim 1, wherein the first local bit line includes:
a lower conductive pillar connected to the lower memory cells of the first memory cell group;
an upper conductive pillar connected to the upper memory cells of the first memory cell group;
a lower bonding pad connected to the lower conductive pillar and between the lower conductive pillar and the upper conductive pillar; and
an upper bonding pad connected to the upper conductive pillar, contacting the lower bonding pad, and between the lower conductive pillar and the upper conductive pillar.

11. The semiconductor device of claim 1, wherein each of the lower and upper memory cells includes a cell transistor and a data storage structure, and
wherein the second structure further includes:
a first upper multiplexer disposed at a level lower than the first global bit line and at a level higher than the cell transistors of the upper memory cells of the first memory cell group; and
a second upper multiplexer disposed at a level lower than the second global bit line and at a level higher than the cell transistors of the upper memory cells in the third memory cell group,
wherein the first upper multiplexer is electrically connected to the first local bit line and the second local bit line, and
wherein the second upper multiplexer is electrically connected to the third local bit line and the fourth local bit line.

12. The semiconductor device of claim 11, wherein the first upper multiplexer is connected to the first global bit line,
wherein the second upper multiplexer is connected to the second global bit line,
wherein the first upper multiplexer includes N first upper select transistors,
wherein the second upper multiplexer includes N second upper select transistors, and
wherein N is a natural number greater than or equal to 2.

13. The semiconductor device of claim 11, wherein the first structure includes:
a first lower multiplexer connected to the first local bit line, disposed at a level higher than the cell transistors of the lower memory cells of the first memory cell group, and vertically overlapping the lower memory cells of the first memory cell group, and
a second lower multiplexer connected to the second local bit line, disposed at the same level as the first lower multiplexer, and vertically overlapping the lower memory cells of the third memory cell group.

14. The semiconductor device of claim 13, wherein the first lower multiplexer includes N first lower select transistors,
wherein the second lower multiplexer includes N second lower select transistors, and
wherein N is a natural number greater than or equal to 2.

15. The semiconductor device of claim 11, wherein each of the first and second upper multiplexers includes upper select transistors, and
wherein each of the upper select transistors has a size different from a size of each of the cell transistors.

16. The semiconductor device of claim 11, wherein each of the first and second upper multiplexers includes upper select transistors,
wherein each of the cell transistors includes:
a first source/drain region and a second source/drain region spaced apart from each other in the first horizontal direction;
a channel region between the first source/drain region and the second source/drain region;
a cell gate electrode vertically overlapping the channel region and extending in the second horizontal direction; and
a cell gate dielectric layer between the cell gate electrode and the channel region,
wherein each of the upper select transistors includes:
a first select source/drain region and a second select source/drain region spaced apart from each other in the first horizontal direction;
a select channel region between the first select source/drain region and the second select source/drain region;
a select gate electrode vertically overlapping the select channel region and extending in the second horizontal direction; and
a select gate dielectric layer between the select gate electrode and the select channel region, and
wherein the first side surface of the first local bit line is connected to each first source/drain region of the cell transistors of the first memory cell group and the first select source/drain region of a first upper select transistor of the first upper multiplexer,
wherein the second side surface of the second local bit line is connected to each first source/drain region of the cell transistors of the second memory cell group and the first select source/drain region of a second upper select transistor of the first upper multiplexer,
wherein the third side surface of the third local bit line is connected to each first source/drain region of the cell transistors of the third memory cell group and the first select source/drain region of a third upper select transistor of the second upper multiplexer, and
wherein the fourth side surface of the fourth local bit line is connected to each first source/drain region of the cell transistors of the fourth memory cell group and the first select source/drain region of a fourth upper select transistor of the second upper multiplexer.

17. A semiconductor device comprising:
a lower structure including a first structure and a second structure bonded to the first structure on the first structure; and
an upper structure disposed on the lower structure and including a peripheral circuit,
wherein the first structure includes lower memory cells arranged three-dimensionally along a vertical direction, a first horizontal direction, and a second horizontal direction, perpendicular to each other,
the second structure includes upper memory cells vertically overlapping the lower memory cells and arranged three-dimensionally along the vertical direction, the first horizontal direction, and the second horizontal direction,
the lower structure further includes local bit lines respectively connected to memory cell groups of the lower and upper memory cells,
the second structure further includes first global bit lines and second global bit lines,
the peripheral circuit includes bit line sense amplifiers connected to a corresponding global bit line of the first and second global bit lines by a routing connection interconnection structure,
each of the first global bit lines is respectively connected to N corresponding first local bit lines among the local bit lines,
each of the second global bit lines is respectively connected to N corresponding second local bit lines among the local bit lines,
“N” is a natural number greater than or equal to 2, and
each of the local bit lines extends through a bonded region between the first structure and the second structure.

18. The semiconductor device of claim 17, wherein side surfaces of the first local bit lines are respectively connected to corresponding first lower memory cells among the lower memory cells and corresponding first upper memory cells among the upper memory cells, and
side surfaces of the second local bit lines are respectively connected to corresponding second lower memory cells among the lower memory cells and corresponding second upper memory cells among the upper memory cells.

19. A semiconductor device comprising:
a bit line sense amplifier;
a global bit line disposed at a level lower than the bit line sense amplifier and connected to the bit line sense amplifier by a routing interconnection structure;
N local bit lines disposed at a level lower than the global bit line, connected to the global bit line, and spaced apart from each other; and
memory cell groups respectively connected to the N local bit lines,
wherein N is a natural number greater than or equal to 2,
wherein each of the memory cell groups includes:
a lower cell group including lower memory cells arranged in a vertical direction; and
an upper cell group including upper memory cells disposed on the lower cell group and arranged in the vertical direction,
wherein each of the lower memory cells and the upper memory cells includes a cell transistor and a data storage structure connected to the cell transistor, and
wherein, in each of the memory cell groups, a distance between a pair of cell transistors adjacent to each other in the vertical direction among the cell transistors of the lower memory cells is smaller than a distance between an uppermost cell transistor among the cell transistors of the lower memory cells and a lowermost cell transistor among the cell transistors of the upper memory cells.

20. The semiconductor device of claim 19, wherein the N local bit lines have recessed side surfaces contacting the lower memory cells and the upper memory cells.
